(19) United States
(12) Patent Application Publication
(10) Pub. No.: US 2026/0007017 A1
(43) Pub. Date: Jan. 1, 2026

(54) DISPLAY DEVICE, METHOD OF MANUFACTURING THE SAME AND ELECTRONIC DEVICE

(71) Applicant: Samsung Display Co., Ltd., Yongin-si (KR)

(72) Inventors: JOONGU LEE, Yongin-si (KR); HYE JIN GWARK, Yongin-si (KR); HWI KIM, Yongin-si (KR); JUNGSUN PARK, Yongin-si (KR); JI-HEE SON, Yongin-si (KR); SEOULKI LEE, Yongin-si (KR); AREUM LEE, Yongin-si (KR); YEONHWA LEE, Yongin-si (KR)

(73) Assignee: Samsung Display Co., Ltd., Yongin-si (KR)

(21) Appl. No.: 19/188,415

(22) Filed: Apr. 24, 2025

(30) Foreign Application Priority Data
Jun. 27, 2024 (KR) 10-2024-0084647

(51) Int. Cl. H10K 59/131; H10K 59/12; H10K 59/80; H10K 59/88

(52) U.S. Cl. CPC H10K 59/131; H10K 59/1201; H10K 59/873; H10K 59/88

(57) ABSTRACT

Provided is a display device including a base layer, a circuit element layer disposed on the base layer, and a display element layer disposed on the circuit element layer and including a pixel definition layer, a light emitting element, a first structure, and a cover layer disposed on the light emitting element. The circuit element layer includes a first auxiliary insulating layer, a second auxiliary insulating layer including an opening, a first metal pattern disposed on the first auxiliary insulating layer, a second metal pattern spaced apart from the first metal pattern and including a second lower metal layer disposed on the first auxiliary insulating layer and disposed in the opening, a second intermediate metal layer disposed on the second lower metal layer, and a second upper metal layer disposed on the second intermediate metal layer, and a dummy pattern disposed on the second metal pattern.

### CROSS-REFERENCE TO RELATED APPLICATION(S)

This application claims priority to and the benefits of Korean Patent Application No. 10-2024-0084647 under 35 U.S.C. § 119, filed on Jun. 27, 2024 in the Korean Intellectual Property Office, the entire contents of which are incorporated herein by reference.

### BACKGROUND

### 1. Technical Field

The disclosure relates to a display device, a method of manufacturing the display device and an electronic device. M ore particularly, the disclosure relates to a display device with improved voltage drop and brightness reduction by increasing a contact area between electrodes, a method of manufacturing the display device and an electronic device including the display device.

### 2. Description of Related Art

Various display devices applied to multimedia devices, such as televisions, mobile phones, tablet computers, computers, and game devices, are being developed. Researches are being conducted on reducing the size of pixels and increasing integration of the pixels to improve a resolution of display devices. Display devices employing a large-sized display panel have a large area, and thus a voltage of pixels arranged in a center of the display devices is lower than that of pixels arranged in an edge of the display devices due to the resistance of electrodes. As a result, a brightness of the center of the display devices is lower than a brightness of other areas of the display devices. To improve the voltage drop and the brightness reduction, a method that connects an auxiliary electrode receiving a power supply voltage to a light emitting element is suggested.

### SUMMARY

The disclosure may provide a display device capable of reducing a resistance of electrodes.

The disclosure may provide a method of manufacturing the display device and an electronic device including the display device.

Embodiments of the disclosure may provide a display device including a base layer, a circuit element layer disposed on the base layer, and a display element layer disposed on the circuit element layer and including a pixel definition layer, a light emitting element, a first structure, and a cover layer disposed on the light emitting element. The circuit element layer may include a first auxiliary insulating layer, a second auxiliary insulating layer including an opening and disposed on the first auxiliary insulating layer, a first metal pattern disposed on the first auxiliary insulating layer and disposed in the opening, a second metal pattern spaced apart from the first metal pattern and including a second lower metal layer disposed on the first auxiliary insulating layer and disposed in the opening, a second intermediate metal layer disposed on the second lower metal layer, and a second upper metal layer disposed on the second intermediate metal layer, and a dummy pattern disposed on the second metal pattern. The pixel definition layer may be disposed on the second auxiliary insulating layer and includes a pixel opening, the light emitting element may include a first electrode of which at least a portion is disposed in the pixel opening, an intermediate layer disposed on the first electrode, the pixel definition layer, the first auxiliary insulating layer, the second auxiliary insulating layer, the first metal pattern, and the second metal pattern, and a second electrode disposed on the intermediate layer, the first structure may be electrically connected to the second electrode and in direct contact with the second intermediate metal layer and the second upper metal layer, the cover layer may include a first material, the first structure may include a second material, and the first material may have a surface energy smaller than a surface energy of the second material.

The second lower metal layer may include a second upper surface substantially parallel to a first direction, the second intermediate metal layer may include a second-first side surface forming a second-first angle with respect to the second upper surface and a second-second side surface forming a second-second angle with respect to the second upper surface, the second upper metal layer may include a second-first lower surface overlapping the second-first side surface in a plan view and a second-second lower surface overlapping the second-second side surface in a plan view, and the first structure may be in direct contact with at least a portion of the second-first side surface and at least a portion of the second-first lower surface.

Each of a width of the second-first lower surface in the first direction and a width of the second-second lower surface in the first direction may be equal to or greater than about 0.1 μm and equal to or smaller than about 1.5 μm.

Each of the second-first angle and the second-second angle may be equal to or greater than about 45 degrees and equal to or smaller than about 80 degrees.

The first structure may not overlap the cover layer in a plan view.

The cover layer may be directly disposed on the second electrode and may be not in contact with the second metal pattern.

The intermediate layer may be in direct contact with the second intermediate metal layer, a surface at which the intermediate layer may be in contact with the second intermediate metal layer may be disposed adjacent to the second lower metal layer, and a surface at which the first structure may be in contact with the second intermediate metal layer may be disposed adjacent to the second upper metal layer.

The first metal pattern may include a first lower metal layer disposed on the first auxiliary insulating layer, a first intermediate metal layer disposed on the first lower metal layer, and a first upper metal layer disposed on the first intermediate metal layer.

The first lower metal layer may include a first upper surface substantially parallel to a first direction, the first intermediate metal layer may include a first side surface forming a first angle with respect to the first upper surface, and the first angle may be equal to or greater than about 45 degrees and equal to or smaller than about 80 degrees.

The dummy pattern may include a first dummy layer, a second dummy layer disposed on the first dummy layer, and a third dummy layer disposed on the second dummy layer and including the first material. The first dummy layer and the intermediate layer include a same material, and the second dummy layer and the second electrode include a same material

Each of the second lower metal layer and the second upper metal layer may have a thickness equal to or greater than about 10 nm and equal to or smaller than about 500 nm, and the second intermediate metal layer may have a thickness equal to or greater than about 300 nm and equal to or smaller than about 2000 nm.

The display device further may include a second structure that is in direct contact with the second intermediate metal layer and the second upper metal layer and electrically connected to the second electrode. The first metal pattern may include a first-first metal pattern and a first-second metal pattern spaced apart from the first-first metal pattern in a first direction, the second metal pattern may be disposed between the first-first metal pattern and the first-second metal pattern, and the second structure may be spaced apart from the first structure in the first direction.

Each of a distance in the first direction between the first-first metal pattern and the second metal pattern and a distance in the first direction between the first-second metal pattern and the second metal pattern may be equal to or greater than about 0.5 μm and equal to or smaller than about 5 μm.

The display element layer further may include a capping layer disposed on the cover layer.

The cover layer may have a thickness equal to or greater than about 5 nm and equal to or smaller than about 50 nm.

The first material may include a fluorine compound.

The second material may include at least one of indium tin oxide (ITO), indium zinc oxide (IZO), zinc oxide (ZnO), indium tin zinc oxide (ITZO), Ag, Mg, Cu, Al, Pt, Pd, Au, Ni, Nd, Ir, Cr, Li, Ca, LiF/Ca, LiF/Al, Mo, Ti, Y b, and Bi.

The first material may have a surface energy greater than about 0 mJ/m² and equal to or smaller than about 30 mJ/m², and the second material may have a surface energy equal to or greater than about 500 mJ/m² and equal to or smaller than about 1000 mJ/m²

Embodiments of the disclosure may provide a method of manufacturing a display device. The method may include providing a preliminary display device including a first auxiliary insulating layer, a second auxiliary insulating layer including an opening and disposed on the first auxiliary insulating layer, a pixel definition layer disposed on the second auxiliary insulating layer and includes a pixel opening, and a first electrode of which at least a portion is disposed in the pixel opening, forming a first metal pattern and a second metal pattern spaced apart from the first metal pattern in the opening, forming an intermediate layer disposed on the first electrode, the pixel definition layer, the first auxiliary insulating layer, the second auxiliary insulating layer, and the first metal pattern and a first dummy layer disposed on the second metal pattern, forming a second electrode disposed on the intermediate layer and a second dummy layer disposed on the first dummy layer, forming a cover layer including a first material disposed on the second electrode and a third dummy layer disposed on the second dummy layer, and providing a second material on the cover layer to form the first structure. The second metal pattern may include a second lower metal layer disposed in the opening and disposed on the first auxiliary insulating layer, a second intermediate metal layer disposed on the second lower metal layer, and a second upper metal layer disposed on the second intermediate metal layer, the first structure may be in direct contact with the second intermediate metal layer and the second upper metal layer, and the first material of the cover layer may have a surface energy smaller than a surface energy of the second material of the first structure.

Embodiments of the disclosure may provide an electronic device including a display device for providing an image. The display device including a base layer, a circuit element layer disposed on the base layer, and a display element layer disposed on the circuit element layer and including a pixel definition layer, a light emitting element, a first structure, and a cover layer disposed on the light emitting element. The circuit element layer may include a first auxiliary insulating layer, a second auxiliary insulating layer including an opening and disposed on the first auxiliary insulating layer, a first metal pattern disposed on the first auxiliary insulating layer and disposed in the opening, a second metal pattern spaced apart from the first metal pattern and including a second lower metal layer disposed on the first auxiliary insulating layer and disposed in the opening, a second intermediate metal layer disposed on the second lower metal layer, and a second upper metal layer disposed on the second intermediate metal layer, and a dummy pattern disposed on the second metal pattern. The pixel definition layer may be disposed on the second auxiliary insulating layer and includes a pixel opening, the light emitting element may include a first electrode of which at least a portion is disposed in the pixel opening, an intermediate layer disposed on the first electrode, the pixel definition layer, the first auxiliary insulating layer, the second auxiliary insulating layer, the first metal pattern, and the second metal pattern, and a second electrode disposed on the intermediate layer, the first structure may be electrically connected to the second electrode and in direct contact with the second intermediate metal layer and the second upper metal layer, the cover layer may include a first material, the first structure may include a second material, and the first material may have a surface energy smaller than a surface energy of the second material.

The second electrode included in the display device may be electrically connected to the second metal pattern receiving the power source voltage, and thus, a brightness reduction is improved.

According to the method of manufacturing the display device, the surface energy of the material included in the cover layer may be different from the surface of the material included in the first structure, and the difference in surface energy may be used to improve a productivity while using existing thermal deposition apparatus.

### BRIEF DESCRIPTION OF THE DRAWINGS

The above and other advantages of the disclosure will become readily apparent by reference to the following detailed description when considered in conjunction with the accompanying drawings wherein:

FIG. 1 is a schematic perspective view of a display device according to an embodiment of the disclosure;

FIG. 2 is an exploded schematic perspective view of a display device according to an embodiment of the disclosure;

FIG. 3 is a schematic cross-sectional view of a display device according to an embodiment of the disclosure;

FIG. 4A is a schematic plan view of a display panel according to an embodiment of the disclosure;

FIG. 4B is a schematic diagram of an equivalent circuit of a pixel according to an embodiment of the disclosure;

FIG. 5 is an enlarged schematic plan view of a display area of a display panel according to an embodiment of the disclosure;

FIG. 6 is a schematic cross-sectional view of a display device taken along line I-I′ of FIG. 5 according to an embodiment of the disclosure;

FIG. 7 is a schematic cross-sectional view of a display device taken along line II-II′ of FIG. 5 according to an embodiment of the disclosure;

FIG. 8 is a schematic flowchart of a method of manufacturing a display device according to an embodiment of the disclosure; and

FIGS. 9 to 15 are schematic cross-sectional views illustrating a method of manufacturing a display device according to an embodiment of the disclosure.

FIG. 16 is a schematic block diagram of an electronic device according to an embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this disclosure, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure. Hereinafter, embodiments of the disclosure will be described with reference to accompanying drawings.

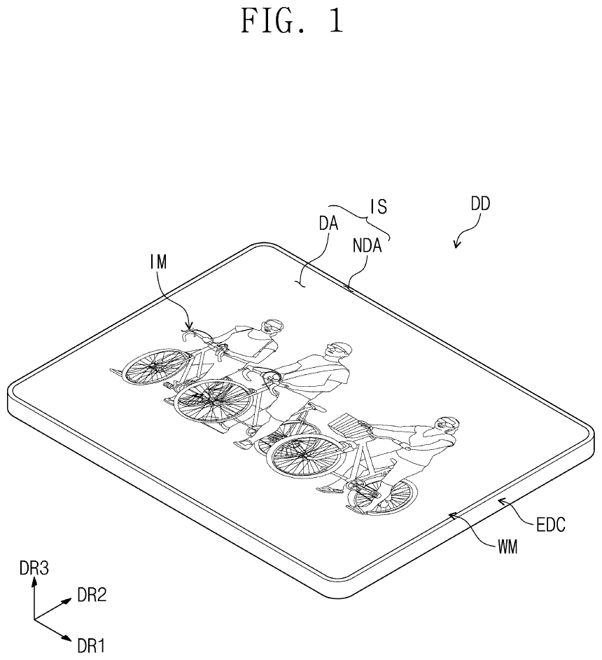

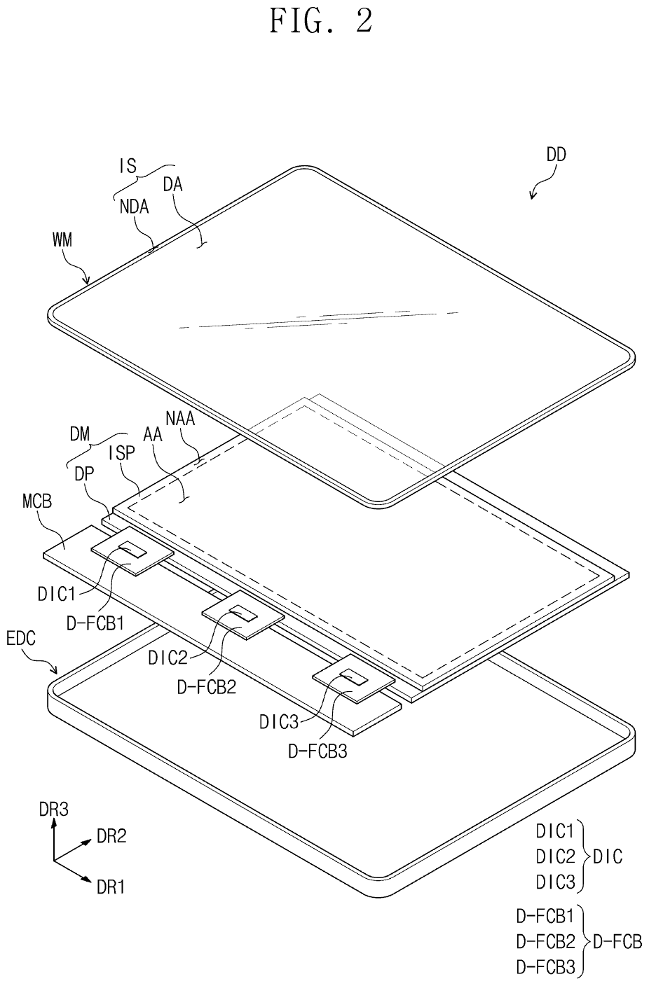

FIG. 1 is a schematic perspective view of a display device DD according to an embodiment of the disclosure. FIG. 2 is an exploded schematic perspective view of the display device DD according to an embodiment of the disclosure.

Referring to FIGS. 1 and 2, the display device DD may be a device activated in response to electrical signals. The display device DD may be applied to a large-sized display device, such as a television set or a monitor. However, these are merely examples, and the display device DD may be applied to other electronic devices as long as they do not depart from the concept of the disclosure. The display device DD may have a rectangular shape defined by long sides extending in a first direction DR1 and short sides extending in a second direction DR2 intersecting the first direction DR1. However, the shape of the display device DD should not be limited to the rectangular shape, and the display device DD may have a variety of shapes. The display device DD may display an image IM toward a third direction DR3 through a display surface IS that is substantially parallel to each of the first direction DR1 and the second direction DR2. The display surface IS through which the image IM is displayed may correspond to a front surface of the display device DD.

In the embodiment, front (or upper) and rear (or lower) surfaces of each member may be defined with respect to the direction in which the image IM is displayed. The front and rear surfaces may be opposite to each other in the third direction DR3, and a normal line direction of each of the front and rear surfaces may be substantially parallel to the third direction DR3.

A separation distance in the third direction DR3 between the front surface and the rear surface may correspond to a thickness in the third direction DR3 of the display device DD. Meanwhile, directions indicated by the first, second, and third directions DR1, DR2, and DR3 may be relative to each other and may be changed to other directions.

The display device DD may sense an external input applied thereto from the outside. The external input may include inputs of various forms provided from the outside of the display device DD. The display device DD may sense an external input generated by a user and applied thereto. The external input by the user may include one of various forms of external inputs, such as a portion of the user's body, light, heat, gaze, or pressure, or a combination thereof. The display device DD may sense the external input applied to a side surface or a rear surface thereof by the user according to a structure thereof, however, it should not be limited thereto. The external input may include inputs generated by an input device, e.g., a stylus pen, an active pen, a touch pen, an electronic pen, an e-pen, or the like.

The display surface IS of the display device DD may include a display area DA and a non-display area NDA. The display area DA may be an area in which the image IM is displayed. The user may view the image IM in the display area DA. In the embodiment, the display area DA may have a quadrangular shape with rounded vertices, however, this is merely an example. The display area DA may have a variety of shapes and should not be limited thereto.

The non-display area NDA may be disposed adjacent to the display area DA. The non-display area NDA may have a predetermined color. The non-display area NDA may surround the display area DA. Accordingly, the display area DA may have a shape substantially defined by the non-display area NDA, however, this is merely an example. The non-display area NDA may be disposed adjacent to only one side of the display area DA or may be omitted. The display device DD may include various embodiments and should not be limited.

Referring to FIG. 2, the display device DD may include a display module DM and a window WM disposed on the display module DM. The display module DM may include a display panel DP and an input sensing layer ISP.

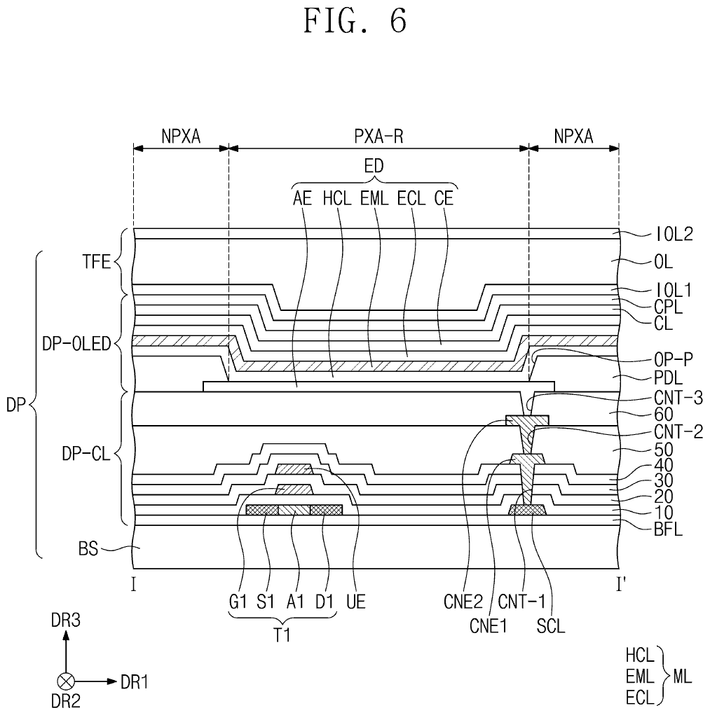

The display panel DP may be a light-emitting type display panel. For example, the display panel DP may be an organic light emitting display panel. A light emitting layer EML (refer to FIG. 6) of the organic light emitting display panel may include an organic light emitting material.

The display panel DP may output the image IM, and the output image IM may be displayed through the display surface IS.

The input sensing layer ISP may be disposed on the display panel DP and may sense the external input. The input sensing layer ISP may be disposed (or directly disposed) on the display panel DP. The input sensing layer ISP may be formed on the display panel DP through successive processes. For example, when the input sensing layer ISP is disposed (or directly disposed) on the display panel DP, an inner adhesive film (not shown) is not disposed between the input sensing layer ISP and the display panel DP. However, the inner adhesive film may be disposed between the input sensing layer ISP and the display panel DP. For example, the input sensing layer ISP may not be manufactured through the successive processes with the display panel DP, and the input sensing layer ISP may be fixed to an upper surface of the display panel DP by the inner adhesive film after being manufactured through a separate process.

The window WM may include a transparent material through which the image IM transmits. For example, the window WM may include glass, sapphire, or plastic. The window WM may be shown as a single layer, however, it should not be limited thereto. The window WM may include multiple layers.

Meanwhile, although not shown in figures, the non-display area NDA of the display device DD may be obtained by printing a material having the predetermined color on an area of the window WM. For example, the window WM may include a light blocking pattern to define the non-display area NDA. The light blocking pattern may be a colored organic layer and may be formed by a coating method.

The window WM may be coupled to the display module DM by an adhesive film. For example, the adhesive film may include an optically clear adhesive film (OCA). However, the adhesive film should not be limited thereto, and the adhesive film may include a conventional adhesive. For example, the adhesive film may include an optically clear resin (OCR) or a pressure sensitive adhesive film (PSA).

An anti-reflective layer may be further disposed between the window WM and the display module DM. The anti-reflective layer may reduce a reflectance with respect to an external light incident thereto from the above of the window WM. The anti-reflective layer according to the disclosure may include a retarder and a polarizer. The retarder may be a film type or liquid crystal coating type and may include a λ/2 retarder and/or a λ/4 retarder. The polarizer may be a film type or liquid crystal coating type. The film type polarizer and retarder may include a stretching type synthetic resin film, and the liquid crystal coating type polarizer and retarder may include liquid crystals aligned in a predetermined alignment. The retarder and the polarizer may be implemented as one polarizing film.

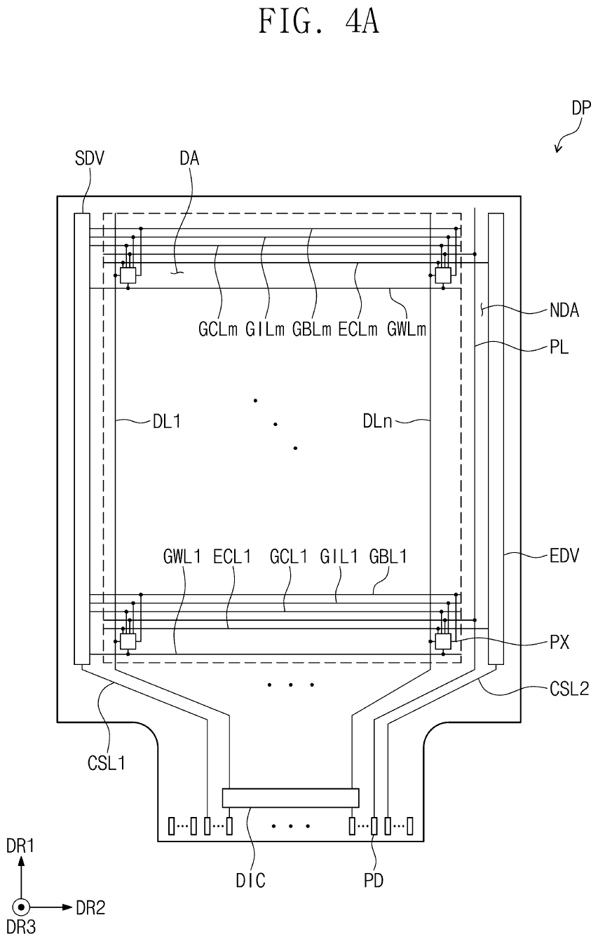

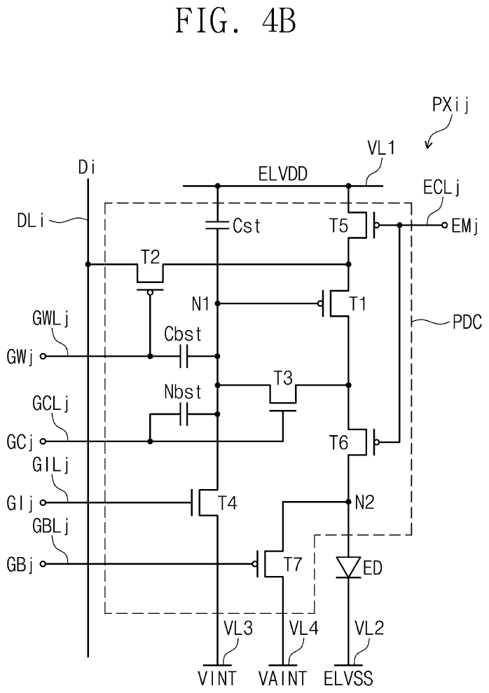

For example, the anti-reflective layer may include color filters. An arrangement of the color filters may be determined by taking into account colors of lights generated by pixels PX (refer to FIG. 4A) included in the display panel DP. For example, the anti-reflective layer may further include a light blocking pattern disposed between the color filters.

The display module DM may display the image IM in response to electrical signals and may transmit/receive information on the external input. The display module DM may include an active area A A and a peripheral area NAA, which are defined therein. The active area AA may be defined as an area through which the image IM provided from the display panel DP exits, i.e., an area through which the image IM is displayed. The active area A A may be defined as an area where the input sensing layer ISP senses the external input applied thereto from the outside. The active area AA of the display module DM may correspond to or overlap at least a portion of the display area DA.

The peripheral area NAA may be disposed adjacent to the active area AA. The peripheral area NAA may be an area where the image IM is not displayed. For instance, the peripheral area NAA may surround the active area AA. However, this is merely an example, and the peripheral area NAA may be defined in various shapes and should not be limited. The peripheral area NA A of the display module DM may correspond to or overlap at least a portion of the non-display area NDA.

The display module DM may further include a main circuit board MCB, flexible circuit films D-FCB, and driving chips DIC. The main circuit board MCB may be electrically connected to the flexible circuit films D-FCB and may be electrically connected to the display panel DP. The flexible circuit films D-FCB may be electrically connected to the display panel DP to electrically connect the display panel DP to the main circuit board MCB. The main circuit board MCB may include multiple driving elements. The driving elements may include a circuit unit to drive the display panel DP. The driving chips DIC may be mounted on the flexible circuit films D-FCB.

For example, the flexible circuit films D-FCB may include a first flexible circuit film D-FCB1, a second flexible circuit film D-FCB2, and a third flexible circuit film D-FCB3. For example, the driving chips DIC may include a first driving chip DIC1, a second driving chip DIC2, and a third driving chip DIC3. The first, second, and third flexible circuit films D-FCB1, D-FCB2, and D-FCB3 may be spaced apart from each other in the first direction DR1 and may be electrically connected to the display panel DP, and thus, the display panel DP may be electrically connected to the main circuit board MCB. The first driving chip DIC1 may be mounted on the first flexible circuit film D-FCB1, and the second driving chip DIC2 may be mounted on the second flexible circuit film D-FCB2. The third driving chip DIC3 may be mounted on the third flexible circuit film D-FCB3. However, the disclosure should not be limited thereto. For example, the display panel DP may be electrically connected to the main circuit board MCB via one flexible circuit film, and only one driving chip may be mounted on the one flexible circuit film. The display panel DP may be electrically connected to the main circuit board MCB via four or more flexible circuit films, and the driving chips may be respectively mounted on the flexible circuit films.

FIG. 2 shows a structure in which the first, second, and third driving chips DIC1, DIC2, and DIC3 are respectively mounted on the first, second, and third flexible circuit films D-FCB1, D-FCB2, and D-FCB3, however, the disclosure should not be limited thereto. For example, the first, second, and third driving chips DIC1, DIC2, and DIC3 may be directly mounted on the display panel DP. For example, portions of the display panel DP on which the first, second, and third driving chips DIC1, DIC2, and DIC3 are mounted may be bent and may be disposed on a rear surface of the display module DM. In another embodiment, the first, second, and third driving chips DIC1, DIC2, and DIC3 may be directly mounted on the main circuit board MCB.

The input sensing layer ISP may be electrically connected to the main circuit board MCB via the flexible circuit films D-FCB, however, the disclosure should not be limited thereto. For example, the display module DM may further include a separate flexible circuit film to electrically connect the input sensing layer ISP to the main circuit board MCB.

The display device DD may further include an external case EDC accommodating the display module DM. The external case EDC may be coupled with the window WM to define an exterior of the display device DD. The external case EDC may absorb impacts applied thereto from the outside and may prevent foreign substances/moisture from entering the display module DM to protect components accommodated in the external case EDC. Meanwhile, for example, the external case EDC may be obtained by assembling multiple accommodating members.

The display device DD may further include an electronic module including various functional modules to operate the display module DM, a power supply module, e.g., a battery, supplying a power source required for an overall operation of the display device DD, and a bracket coupled with the display module DM and/or the external case EDC to divide an inner space of the display device DD.

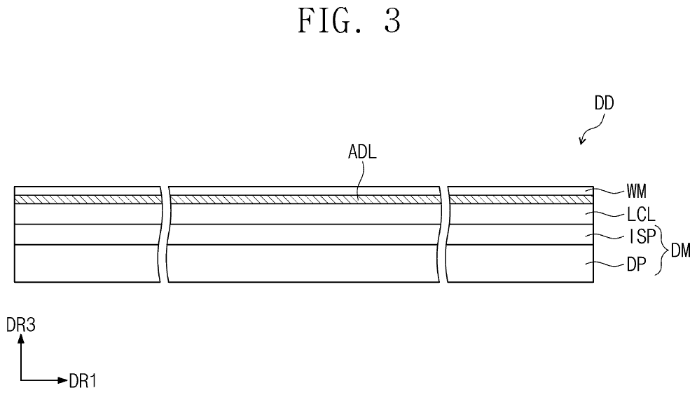

FIG. 3 is a schematic cross-sectional view of the display device DD according to an embodiment of the disclosure. As depicted in FIG. 3, the display device DD is simply shown to illustrate a stacking relationship of functional panels and/or functional units constituting the display device DD.

The display device DD may include the display module DM, a light control layer LCL, and the window WM. The display module DM may include the display panel DP and the input sensing layer ISP. In another embodiment, the input sensing layer ISP may be omitted.

The display panel DP may generate the image IM (refer to FIG. 1). The display panel DP may include the pixels PX (refer to FIG. 4A).

The input sensing layer ISP may be disposed on the display panel DP. The input sensing layer ISP may obtain coordinate information on the external input, e.g., a touch event. The input sensing layer ISP may sense the external input by a capacitive method.

The light control layer LCL may be disposed on the input sensing layer ISP. The light control layer LCL may control a path of a light generated by the display panel DP. The light control layer LCL may reduce a reflectance with respect to a natural light (or a sunlight) incident thereto from above the window WM.

The window WM may be disposed on the light control layer LCL. The window WM may be coupled with the light control layer LCL by a window adhesive layer ADL interposed therebetween. The window adhesive layer ADL may be a pressure sensitive adhesive (PSA) film or an optically clear adhesive (OCA).

FIG. 4A is a schematic plan view of the display panel DP according to an embodiment of the disclosure.

Referring to FIG. 4A, the display panel DP may include the display area DA and the non-display area NDA disposed around the display area DA. The display area DA and the non-display area NDA may be distinguished from each other by a presence or absence of the pixels PX. The pixels PX may be disposed in the display area DA. A scan driver SDV, a data driver, and an emission driver EDV may be disposed in the non-display area NDA. The data driver may be a circuit provided in a driving chip DIC.

The display panel DP may include the pixels PX, multiple initialization scan lines GIL1 to GILm, multiple compensation scan lines GCL1 to GCLm, multiple write scan lines GWL1 to GWLm, multiple black scan lines GBL1 to GBLm, multiple emission control lines ECL1 to ECLm, multiple data lines DL1 to DLn, first and second control lines CSL1 and CSL2, a driving voltage line PL, and multiple pads PD arranged in the second direction DR2. In the embodiment, each of the “m” and the “n” may be a natural number equal to or greater than 2.

The pixels PX may be electrically connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in a direction parallel to the second direction DR2 and may be electrically connected to the scan driver SDV. The data lines DL1 to DLn may extend in a direction parallel to the first direction DR1 and may be electrically connected to the driving chip DIC. The emission control lines ECL1 to ECLm may extend in the first direction DR1 and may be electrically connected to the emission driver EDV.

The driving voltage line PL may include a portion extending in the first direction DR1 and a portion extending in the second direction DR2. The portion extending in the first direction DR1 and the portion extending in the second direction DR2 may be disposed on different layers from each other. The driving voltage line PL may provide a driving voltage to the pixels PX.

The first control line CSL1 may be electrically connected to the scan driver SDV. The second control line CSL2 may be electrically connected to the emission driver EDV.

The driving chip DIC, the driving voltage line PL, the first control line CSL1, and the second control line CSL2 may be electrically connected to the pads PD. The flexible circuit film D-FCB (refer to FIG. 2) may be electrically connected to the pads PD through an anisotropic conductive adhesive layer. The pads PD may connect the flexible circuit film D-FCB (refer to FIG. 2) to the display panel DP. The pads PD may be electrically connected to corresponding pixels PX through the driving voltage line PL, the first control line CSL1, and the second control line CSL2.

The pads PD may further include input pads. The input pads may connect the flexible circuit films D-FCB to the input sensing layer ISP (refer to FIG. 2), however, the disclosure should not be limited thereto. The input pads may be disposed in the input sensing layer ISP (refer to FIG. 2) and may be electrically connected to a circuit board different from the circuit board to which the pads PD are connected. The input sensing layer ISP (refer to FIG. 2) may be omitted, and the pads PD may not further include the input pads.

FIG. 4B is a schematic diagram of an equivalent circuit of a pixel PX ij according to an embodiment of the disclosure.

FIG. 4B shows a schematic diagram of an equivalent circuit of the pixel PX ij among the pixels PX of FIG. 4A. Since the pixels PX (refer to FIG. 4A) have substantially the same configuration as each other, the circuit configuration of the pixel PX ij will be described in detail, and detailed descriptions of the other pixels will be omitted.

Referring to FIGS. 4A and 4B, the pixel PX ij may be electrically connected to an i-th data line DLi among the data lines DL1 to DLn, a j-th initialization scan line GILj among the initialization scan lines GIL1 to GILm, a j-th compensation scan line GCLj among the compensation scan lines GCL1 to GCLm, a j-th write scan line GWLj among the write scan lines GWL1 to GWLm, a j-th black scan line GBLj among the black scan lines GBL1 to GBLm, a j-th emission control line ECLj among the emission control lines ECL1 to ECLm, first and second driving voltage lines VL1 and VL2, and first and second initialization voltage lines VL3 and VL4. The “i” may be an integer number equal to or greater than 1 and equal to or smaller than n, and the “j” may be an integer number equal to or greater than 1 and equal to or smaller than m.

The pixel PX ij may include a light emitting element ED and a pixel circuit PDC. The light emitting element ED may be a light emitting diode. For example, the light emitting element ED may be an organic light emitting diode including an organic light emitting layer, however, it should not be limited. The pixel circuit PDC may control an amount of current flowing through the light emitting element ED in response to a data signal Di. The light emitting element ED may emit a light with a predetermined luminance corresponding to the amount of current provided from the pixel circuit PDC.

The pixel circuit PDC may include first, second, third, fourth, fifth, sixth, and seventh transistors T1, T2, T3, T4, T5, T6, and T7 and first, second, and third capacitors Cst, Cbst, and Nbst. The configuration of the pixel circuit PDC should not be limited to the embodiment shown in FIG. 4B. The pixel circuit PDC shown in FIG. 4B is merely an example, and the configuration of the pixel circuit PDC may be changed. For example, in another embodiment, the pixel circuit PDC may include less or more than seven transistors and less or more than three capacitors.

At least one of the first to seventh transistors T1 to T7 may include a low-temperature polycrystalline silicon (LTPS) as its semiconductor layer. At least one of the first to seventh transistors T1 to T7 may include an oxide material as its semiconductor layer. For example, each of the third and fourth transistors T3 and T4 may be an oxide semiconductor transistor, and each of the first, second, fifth, sixth, and seventh transistors T1, T2, T5, T6, and T7 may be a low-temperature polycrystalline silicon (LTPS) transistor.

In detail, the first transistor T1, which affects (or directly affects) a luminance of the light emitting element ED, may include the semiconductor layer containing polycrystalline silicon with high reliability, and thus, the display device with high resolution may be implemented. Meanwhile, since the oxide semiconductor has a high carrier mobility and a low leakage current, the voltage drop is not large even though the driving time is long. For example, even in case that the pixel circuit PDC is driven at low frequency, a change in color of the image due to the voltage drop is not large, and thus, the pixel circuit PDC may be driven at low frequency. As described above, since the oxide semiconductor has low leakage current, at least one of the third transistor T3 and the fourth transistor T4, which are connected to a gate electrode of the first transistor T1, may include the oxide semiconductor. Thus, the leakage current may be prevented from flowing to the gate electrode of the first transi stor T1, and power consumption may be reduced.

Some of the first to seventh transistors T1 to T7 may be a P-type transistor, and the other of the first to seventh transistors T1 to T7 may be an N-type transistor. For example, each of the first, second, fifth, sixth, and seventh transistors T1, T2, T5, T6, and T7 may be the P-type transistor, and each of the third and fourth transistors T3 and T4 may be the N-type transistor.

The configuration of the pixel circuit PDC should not be limited to that shown in FIG. 4B. The pixel circuit PDC shown in FIG. 4B is merely an example, and the configuration of the pixel circuit PDC may be changed. For example, all the first to seventh transistors T1 to T7 may be the P-type transistor or the N-type transistor. The first, second, fifth, and sixth transistors T1, T2, T5, and T6 may be the P-type transistor, and the third, fourth, and seventh transistors T3, T4, and T7 may be the N-type transistor.

The j-th initialization scan line GILj, the j-th compensation scan line GCLj, the j-th write scan line GWLj, the j-th black scan line GB Lj, and the j-th emission control line ECLj may transmit a j-th initialization scan signal GIj, a j-th compensation scan signal GCj, a j-th write scan signal GWj, a j-th black scan signal GBj, and a j-th emission control signal EM j to the pixel PX ij, respectively. The i-th data line DLi may transmit an i-th data signal Di to the pixel PX ij. The i-th data signal Di may have a voltage level corresponding to the image signal input to the display device DD (refer to FIG. 1).

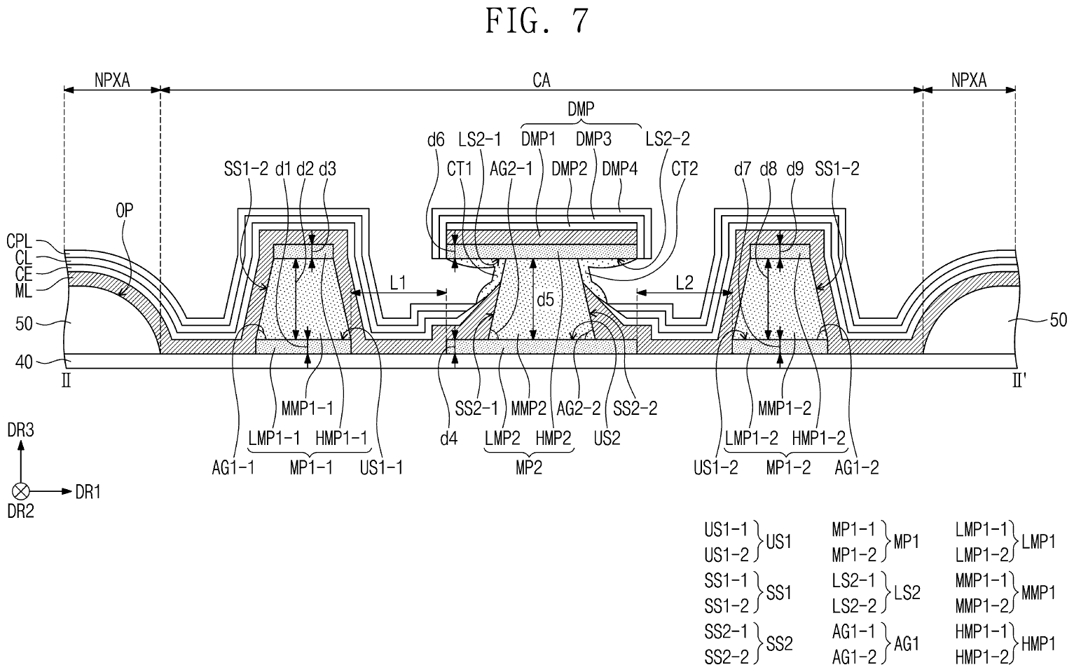

The first and second driving voltage lines VL1 and VL2 may transmit a first driving voltage ELVDD and a second driving voltage ELVSS to the pixel PX ij, respectively. A second metal pattern (refer to MP2 of FIG. 7) may transmit the second driving voltage ELVSS to the pixel PX ij. The second metal pattern will be described in detail with reference to FIG. 7. The first and second initialization voltage lines VL3 and VL4 may transmit a first initialization voltage VINT and a second initialization voltage VAINT to the pixel PX ij, respectively.

The first transistor T1 may be connected between the first driving voltage line VL1 receiving the first driving voltage ELVDD and the light emitting element ED. The first transistor T1 may include a first electrode connected to the first driving voltage line VL1 via the fifth transistor T5, a second electrode connected to a pixel electrode (or referred to as the anode) of the light emitting element ED via the sixth transistor T6, and a third electrode (e.g., the gate electrode) connected to an end (e.g., a first node N1) of the first capacitor Cst. The first transistor T1 may receive the i-th data signal Di transmitted by the i-th data line DLi in response to a switching operation of the second transistor T2 and may supply a driving current to the light emitting element ED.

The second transistor T2 may be connected between the i-th data line DLi and the first electrode of the first transistor T1. The second transistor T2 may include a first electrode connected to the i-th data line DLi, a second electrode connected to the first electrode of the first transistor T1, and a third electrode (e.g., a gate electrode) connected to the j-th write scan line GWLj. The second transistor T2 may be turned on in response to the j-th write scan signal GWj applied thereto via the j-th write scan line GWLj and may transmit the i-th data signal Di applied thereto via the i-th data line DLi to the first electrode of the first transistor T1. An end of the second capacitor Cbst may be connected to the third electrode of the second transistor T2, and another end of the second capacitor Cbst may be connected to the first node N1.

The third transistor T3 may be connected between the second electrode of the first transistor T1 and the first node N1. The third transistor T3 may include a first electrode connected to the third electrode of the first transistor T1, a second electrode connected to the second electrode of the first transistor T1, and a third electrode (e.g., a gate electrode) connected to the j-th compensation scan line GCLj. The third transistor T3 may be turned on in response to the j-th compensation scan signal GCj applied thereto via the j-th compensation scan line GCLj and may connect the third electrode and the second electrode of the first transistor T1 to each other to allow the first transistor T1 to be connected in a diode configuration. An end of the third capacitor Nbst may be connected to the third electrode of the third transistor T3, and another end of the third capacitor Nbst may be connected to the first node N1.

The fourth transistor T4 may be connected between the first initialization voltage line VL3 to which the first initialization voltage VINT is applied and the first node N1. The fourth transistor T4 may include a first electrode connected to the first initialization voltage line VL3 to which the first initialization voltage VINT is applied, a second electrode connected to the first node N1, and a third electrode (e.g., a gate electrode) connected to the j-th initialization scan line GILj. The fourth transistor T4 may be turned on in response to the j-th initialization scan signal GIj applied thereto via the j-th initialization scan line GILj. The turned-on fourth transistor T4 may transmit the first initialization voltage VINT to the first node N1 to initialize an electric potential of the third electrode of the first transistor T1, i.e., an electric potential of the first node N1.

The fifth transistor T5 may include a first electrode connected to the first driving voltage line VL1, a second electrode connected to the first electrode of the first transistor T1, and a third electrode (e.g., a gate electrode) connected to the j-th emission control line ECLj. The sixth transistor T6 may include a first electrode connected to the second electrode of the first transistor T1, a second electrode connected to the pixel electrode of the light emitting element ED, and a third electrode (e.g., a gate electrode) connected to the j-th emission control line ECLj.

The fifth transistor T5 and the sixth transistor T6 may be substantially simultaneously turned on in response to the j-th emission control signal EM j applied thereto via the j-th emission control line ECLj. The first driving voltage ELVDD applied via the turned-on fifth transistor T5 may be compensated for by the first transistor T1 connected in the diode configuration and may be transmitted to the light emitting element ED via the sixth transistor T6.

The seventh transistor T7 may include a first electrode connected to the second initialization voltage line VL4 to which the second initialization voltage VAINT is applied, a second electrode connected to the second electrode of the sixth transistor T6, and a third electrode (e.g., a gate electrode) connected to the j-th black scan line GBLj. The second initialization voltage VAINT may have a voltage level equal to or lower than that of the first initialization voltage VINT.

The end of the first capacitor Cst may be connected to the third electrode of the first transistor T1, and another end of the first capacitor Cst may be connected to the first driving voltage line VL1. The cathode of the light emitting element ED may be connected to the second driving voltage line VL2 that transmits the second driving voltage ELVSS. The second driving voltage ELVSS may have a voltage level lower than that of the first driving voltage ELVDD.

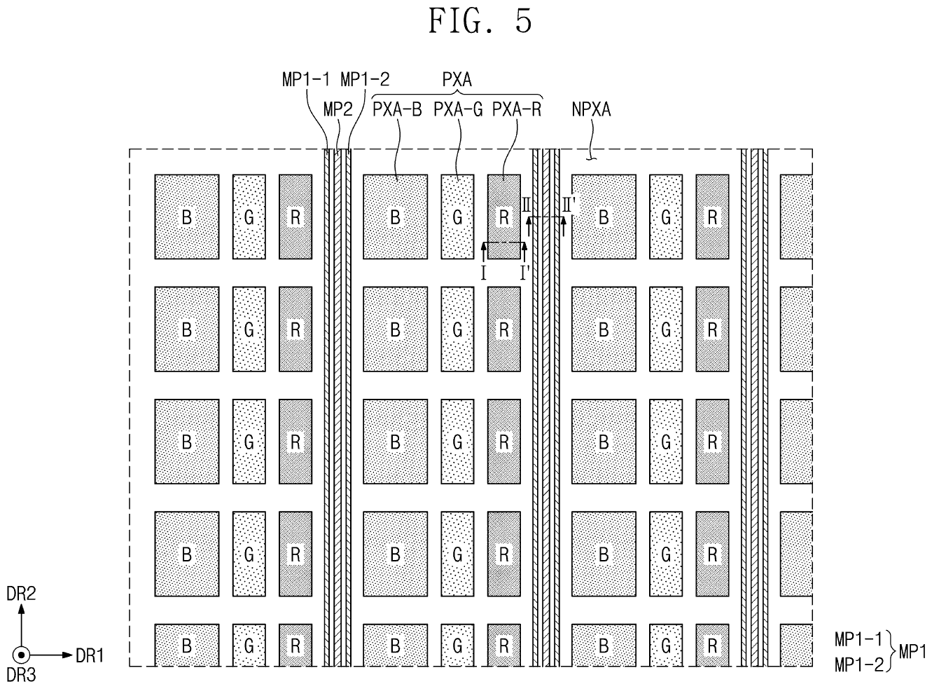

FIG. 5 is an enlarged schematic plan view of the display area of the display panel according to an embodiment of the disclosure.

FIG. 5 illustrates an arrangement relationship of pixel areas PXA, a non-light-emitting area NPXA, a first metal pattern MP1, and the second metal pattern MP2. Pixel areas PXA may include the first, second, and third pixel areas PXA-B, PXA-G, and PXA-R.

Referring to FIG. 5, each of the first metal pattern MP1 and the second metal pattern MP2 may be provided in plural and may not overlap the first, second, and third pixel areas PXA-B, PXA-R, and PXA-G in a plan view. Each of the first metal pattern MP1 and the second metal pattern MP2 may extend in the second direction DR2. Each of the first metal pattern MP1 and the second metal pattern MP2 may be disposed between the first pixel area PXA-B and the third pixel area PXA-R in the first direction DR1 in a plan view.

The first metal pattern MP1 may include a first-first metal pattern MP1-1 and a first-second metal pattern MP1-2, which are disposed between the first pixel area PXA-B and the third pixel area PXA-R in the first direction DR1. The second metal pattern MP2 may be disposed between the first-first metal pattern MP1-1 and the first-second metal pattern MP1-2. FIG. 5 shows a structure in which the first metal pattern MP1 and the second metal pattern MP2 are disposed between the first pixel area PXA-B and the third pixel area PXA-R, however, the first metal pattern MP1 and the second metal pattern MP2 may not be disposed between one first pixel area PXA-B and the third pixel area PXA-R disposed adjacent to the one first pixel area PXA-B. For example, the number of each of the first-first metal patterns MP1-1, the first-second metal patterns MP1-2, and the second metal patterns MP2 may be different from that shown in FIG. 5.

The second metal pattern MP2 may transmit the second driving voltage ELVSS (refer to FIG. 4B) to the light emitting element ED (refer to FIG. 4B). Since the second driving voltage ELVSS (refer to FIG. 4B) is generated from the outer side of the display device, the voltage and brightness at the center of the display device may be reduced by the resistance of the second driving voltage line VL2 (refer to FIG. 4B) that transmits the second driving voltage ELVSS (refer to FIG. 4B). The second metal pattern MP2 may receive the second driving voltage ELVSS, may extend in the second direction DR2, and may be electrically connected to a second electrode CE (refer to FIG. 6) of the light emitting element ED (refer to FIG. 6), and thus, the voltage and brightness at the center of the display device may be prevented from being deteriorated.

The pixel areas PXA may be areas from which the light generated by the light emitting element ED (refer to FIG. 4B) exits. Each of the pixel areas PXA may correspond to the pixel PX (refer to FIG. 4A). The pixel areas PXA may be spaced apart from each other in a plan view. As shown in FIG. 5, the first pixel area PXA-B, the second pixel area PXA-G, and the third pixel area PXA-R may be sequentially arranged in the first direction DR1. In case that the structure in which the first pixel area PXA-B, the second pixel area PXA-G, and the third pixel area PXA-R are sequentially arranged in the first direction DR1 is defined as a unit pixel area, the unit pixel area may be arranged in each of the first direction DR1 and the second direction DR2. The pixel areas PXA may be arranged in a stripe pattern. Different from the arrangement of the pixel areas PXA shown in FIG. 5, the pixel areas PXA may be arranged in a pentile pattern (PENTILE™) or a diamond pattern (Diamond Pixel™). The non-light-emitting area NPXA may be an area between the pixel areas PXA disposed adjacent to each other. The non-light-emitting area NPXA may surround each of the pixel areas PXA.

The first, second, and third pixel areas PXA-B, PXA-G, and PXA-R may respectively provide first, second, and third color lights having different colors. For example, the first color light may be a blue light, the second color light may be a green light, and the third color light may be a red light, however, the first to third color lights should not be limited thereto.

Some of the first, second, and third pixel areas PXA-B, PXA-G, and PXA-R may have different sizes in a plan view. The size of the first pixel area PXA-B emitting the blue light may be greater than the size of the second pixel area PXA-G emitting the green light and the size of the third pixel area PXA-R emitting the red light. However, the relationship in size between the first, second, and third pixel areas PXA-B, PXA-G, and PXA-R depending on the colors of the emitted lights should not be limited thereto and may be variously changed depending on the design of the display module DM (refer to FIG. 2). The first, second, and third pixel areas PXA-B, PXA-G, and PXA-R may have substantially the same size in a plan view. FIG. 5 illustrates the structure in which the size of the first pixel area PXA-B is greater than the size of each of the second pixel area PXA-G and the third pixel area PXA-R. Meanwhile, the size of the pixel area PXA may mean a size in a plan view defined by the first direction DR1 and the second direction DR2.

The first, second, and third pixel areas PXA-B, PXA-G, and PXA-R may have various shapes in a plan view. For example, the first, second, and third pixel areas PXA-R, PXA-G, and PXA-B may have a polygonal shape, a circular shape, or an oval shape. In FIG. 5, each of the first, second, and third pixel areas PXA-B, PXA-G, and PXA-R is shown as having a rectangular shape.

Meanwhile, the shape, size, and arrangement of the first, second, and third pixel areas PXA-B, PXA-G, and PXA-R of the display module DM (refer to FIG. 2) may be variously designed depending on the colors of the emitted lights, the size of the display module DM (refer to FIG. 2), and the configuration of the display module DM (refer to FIG. 2), however, they should not be limited to the embodiment shown in FIG. 5.

FIG. 6 is a schematic cross-sectional view of the display device taken along line I-I′ of FIG. 5 according to an embodiment of the disclosure.

The line I-I′ of FIG. 5 is shown to cross the third pixel area PXA-R, and descriptions of the third pixel area PXA-R may be applied to the first and second pixel areas PXA-B and PXA-G.

Referring to FIG. 6, the display panel DP may include a base layer BS, a circuit element layer DP-CL, and a display element layer DP-OLED.

The base layer BS may include a synthetic resin film. The base layer BS may include a glass substrate, a metal substrate, or an organic/inorganic composite substrate. For example, the base layer BS may be a silicon substrate containing silicon. The base layer BS may be a silicon wafer.

At least one inorganic layer may be disposed on an upper surface of the base layer BS. The circuit element layer DP-CL may be disposed on the base layer BS. The circuit element layer DP-CL may include a buffer layer BFL, first, second, and third insulating layer 10, 20, and 30, and first, second, and third auxiliary insulating layers 40, 50, and 60.

The buffer layer BFL may increase an adhesive force between the base layer BS and a semiconductor pattern. The buffer layer BFL may include a silicon oxide layer and a silicon nitride layer, and the silicon oxide layer and the silicon nitride layer may be alternately stacked with each other.

The circuit element layer DP-CL may further include multiple insulating layers, a semiconductor pattern, a conductive pattern, and a signal line. An insulating layer, a semiconductor layer, and a conductive layer may be formed by coating and deposition processes. Then, the insulating layer, the semiconductor layer, and the conductive layer may be selectively patterned by a photolithography process and an etching process. The semiconductor pattern, the conductive pattern, and the signal line, which are included in the circuit element layer DP-CL and the display element layer DP-OLED, may be formed by the above-mentioned method.

The semiconductor pattern may be disposed on the buffer layer BFL. The semiconductor pattern may include polysilicon; however, it should not be limited thereto. The semiconductor pattern may include amorphous silicon or metal oxide. The semiconductor pattern may be arranged with a specific rule over multiple light emitting areas. The semiconductor pattern may have different electrical properties depending on whether it is doped or not. The semiconductor pattern may include a first region having a relatively high doping concentration and a second region having a relatively low doping concentration. The first region may be doped with the N-type dopant or the P-type dopant. A P-type transistor may include the first region doped with the P-type dopant.

The first region may have a conductivity greater than that of the second region and may substantially serve as an electrode or signal line. The second region may substantially correspond to an active (or a channel) of a transistor. In another embodiment, a portion of the semiconductor pattern may be the active of the transistor, another portion of the semiconductor pattern may be a source or a drain of the transistor, and the other portion of the semiconductor pattern may be a conductive area.

As shown in FIG. 6, a source S1, an active A1, and a drain D1 of a first transistor T1 may be formed from the semiconductor pattern. FIG. 6 shows a portion of a signal transmission line SCL formed from the semiconductor pattern. Although not shown in figures, the signal transmission line SCL may be electrically connected to the drain D1 of the first transistor T1 in a plan view.

The first, second, and third insulating layers 10, 20, and 30 and first, second, and third auxiliary insulating layers 40, 50, and 60 may be disposed on the buffer layer BFL. Each of the first to third insulating layers 10 to 30 and each of the first to third auxiliary insulating layers 40 to 60 may be an inorganic layer or an organic layer. A gate G 1 may be disposed on the first insulating layer 10 and may overlap the active A1 in the third direction DR3. An upper electrode UE may be disposed on the second insulating layer 20. A first connection electrode CNE1 may be disposed on the third insulating layer 30. The first connection electrode CNE1 may be electrically connected to the signal transmission line SCL via a contact hole CNT-1 defined through the first, second, and third insulating layers 10, 20, and 30. The first auxiliary insulating layer 40, the second auxiliary insulating layer 50, and the third auxiliary insulating layer 60 may be disposed on the third insulating layer 30. According to an embodiment, each of the first auxiliary insulating layer 40, the second auxiliary insulating layer 50, and the third auxiliary insulating layer 60 may be an organic layer.

A second connection electrode CNE2 may be disposed on the second auxiliary insulating layer 50. The second connection electrode CNE2 may be electrically connected to the first connection electrode CNE1 via a contact hole CNT-2 defined through the first auxiliary insulating layer 40 and the second auxiliary insulating layer 50.

The display element layer DP-OLED may be disposed on the circuit element layer DP-CL. The display element layer DP-OLED may include a light emitting element ED, a pixel definition layer PDL, and a cover layer CL.

The light emitting element ED may be disposed on the third auxiliary insulating layer 60. The light emitting element ED may include a first electrode A E, a second electrode CE, and an intermediate layer ML disposed between the first electrode AE and the second electrode CE. The intermediate layer ML may include a hole control layer HCL, the light emitting layer EML disposed on the hole control layer HCL, and an electron control layer ECL disposed on the light emitting layer EML. A portion of the intermediate layer ML may overlap a pixel opening OP-P in a plan view.

The first electrode A E may be disposed on the third auxiliary insulating layer 60. The first electrode A E may be electrically connected to the second connection electrode CNE2 via a contact hole CNT-3 defined through the third auxiliary insulating layer 60. The pixel definition layer PDL may be disposed on the third auxiliary insulating layer 60. The pixel opening OP-P may be defined through the pixel definition layer PDL. At least a portion of the first electrode A E may be exposed through the pixel opening OP-P. At least the portion of the first electrode A E may be disposed in the pixel opening OP-P.

The pixel definition layer PDL may include a light absorbing material. The pixel definition layer PDL may include a black coloring agent. The black coloring agent may include a black dye or a black pigment. The black coloring agent may include a metal material, such as carbon black, chromium, or an oxide thereof.

The hole control layer HCL may be disposed on the first electrode A E. The hole control layer HCL may be commonly disposed in the third pixel area PXA-G and the non-light-emitting area NPXA. The hole control layer HCL may include a hole transport layer and may further include a hole injection layer.

The light emitting layer EML may be disposed between the first electrode A E and the second electrode CE. The light emitting layer EML may be disposed on the hole control layer HCL. The light emitting layer EML may be commonly disposed in the third pixel area PXA-G and the non-light-emitting area NPXA.

The electron control layer ECL may be disposed on the light emitting layer EML. The electron control layer ECL may include an electron transport layer and may further include an electron injection layer.

The second electrode CE may be disposed above the first electrode A E. The second electrode CE may be disposed on the electron control layer ECL. The electron control layer ECL and the second electrode CE may be disposed (or commonly disposed) in the third pixel area PX A-R and the non-light-emitting area NPXA. The second electrode CE may include at least one of indium tin oxide (ITO), indium zinc oxide (IZO), zinc oxide (ZnO), indium tin zinc oxide (ITZO), Ag, Mg, Cu, Al, Pt, Pd, Au, Ni, Nd, Ir, Cr, Li, Ca, LiF/Ca, LiF/Al, Mo, Ti, and Y b.

The cover layer CL may be disposed on the light emitting element ED. The cover layer CL may be disposed (or directly disposed) on the second electrode CE. The cover layer CL may include a first material. The cover layer CL may include a fluorine compound as the first material. The cover layer CL may include F atoms in an amount of about 20 at % or more based on the number of atoms of the cover layer CL. The cover layer CL may include at least one of a fluorine-based monomer, a fluorine-based polymer, and a silicon-fluorine compound. The first material included in the cover layer CL may have a surface energy greater than about 0 mJ/m² and equal to or smaller than about 30 mJ/m². For example, the first material included in the cover layer CL may have the surface energy of about 15 mJ/m². The cover layer CL may have a thickness equal to or greater than about 5 nm and equal to or smaller than about 50 nm. For example, the cover layer CL may have the thickness of about 25 nm.

The display element layer DP-OLED may further include a capping layer CPL disposed on the cover layer CL. The capping layer CPL may be disposed (or directly disposed) on the cover layer CL. The capping layer CPL may be disposed (or commonly disposed) in the third pixel area PXA-R and the non-light-emitting area NPXA. The capping layer CPL may include an inorganic material. The capping layer CPL may be formed through a sputtering deposition process. The capping layer CPL may cover the second electrode CE and thus may protect the second electrode CE and the light emitting layer EML from external moisture and contaminants. A light totally reflected at an interface between the second electrode CE and the capping layer CPL may be reduced by adjusting a refractive index and a thickness of the capping layer CPL.

The display panel DP may further include an encapsulation layer TFE disposed on the display element layer DP-OLED. The encapsulation layer TFE may encapsulate the display element layer DP-OLED. The encapsulation layer TFE may include a single layer or multiple layers stacked on each other. The encapsulation layer TFE may include at least one organic layer.

The encapsulation layer TFE may include a first inorganic layer IOL1, an organic layer OL, and a second inorganic layer IOL2. The first inorganic layer IOL1 may be disposed on the capping layer CPL. The organic layer OL may be disposed on the first inorganic layer IOL1. The second inorganic layer IOL2 may be disposed on the organic layer OL and may cover the organic layer OL.

The first inorganic layer IOL1 and the second inorganic layer IOL2 may protect the display element layer DP-OLED from moisture and oxygen, and the organic layer OL may protect the display element layer DP-OLED from a foreign substance such as dust particles.

FIG. 7 is a schematic cross-sectional view of the display device taken along line II-II′ of FIG. 5 according to an embodiment of the disclosure. In FIG. 7, detailed descriptions of the same elements as those described with reference to FIG. 6 will be omitted. In FIG. 7, the third auxiliary insulating layer 60 is omitted.

Referring to FIG. 7, the second auxiliary insulating layer 50 may be provided with an opening OP defined therethrough. At least a portion of the first auxiliary insulating layer 40 may be exposed through the opening OP. The display area DA (refer to FIG. 1) may further include a contact area CA defined by the opening OP.

The circuit element layer DP-CL (refer to FIG. 6) may further include the first metal pattern MP1, the second metal pattern MP2, and a dummy pattern DMP, and the display element layer DP-OLED (refer to FIG. 6) may further include a first structure CT1 (or a first member CT1).

The first metal pattern MP1 may be disposed on the first auxiliary insulating layer 40 and may be disposed in the opening OP. The first metal pattern MP1 may overlap the contact area CA in a plan view. The first metal pattern MP1 may include a metal material. For example, the first metal pattern MP1 may include at least one of aluminum (Al) or titanium (Ti). The first metal pattern MP1 may include a first lower metal layer LMP1, a first intermediate metal layer MMP1, and a first upper metal layer HMP1.

The first lower metal layer LMP1 may be disposed on the first auxiliary insulating layer 40. The first lower metal layer LMP1 may be disposed (or directly disposed) on the first auxiliary insulating layer 40. The first lower metal layer LMP1 may include a first upper surface US1 substantially parallel to the first direction DR1. The first intermediate metal layer MMP1 may be disposed on the first lower metal layer LMP1. The first intermediate metal layer MMP1 may include a first side surface SS1 that forms a first angle AG1 with respect to the first upper surface US1. The first angle AG1 may be equal to or greater than about 45 degrees and equal to or smaller than about 80 degrees. For example, the first angle AG1 may be about 60 degrees. The first upper metal layer HMP1 may be disposed on the first intermediate metal layer MMP1. Each of the first lower metal layer LMP1 and the first upper metal layer HMP1 may include titanium (Ti). The first intermediate metal layer MMP1 may include aluminum (Al).

Each of the first lower metal layer LMP1 and the first upper metal layer HMP1 may have a thickness equal to or greater than about 10 nm and equal to or smaller than about 500 nm. The first intermediate metal layer MMP1 may have a thickness equal to or greater than about 300 nm and equal to or smaller than about 2000 nm. For example, the thickness of each of the first lower metal layer LMP1 and the first upper metal layer HMP1 may be about 100 nm, and the thickness of the first intermediate metal layer MMP1 may be about 1000 nm.

The first metal pattern MP1 may include a first-first metal pattern MP1-1 and a first-second metal pattern MP1-2. The first-first metal pattern MP1-1 may include a first-first lower metal layer LMP1-1 disposed on the first auxiliary insulating layer 40, a first-first intermediate metal layer MMP1-1 disposed on the first-first lower metal layer LMP1-1, and a first-first upper metal layer HMP1-1 disposed on the first-first intermediate metal layer MMP1-1.

The first-first lower metal layer LMP1-1 may be disposed (or directly disposed) on the first auxiliary insulating layer 40. The first-first lower metal layer LMP1-1 may include a first-first upper surface US1-1 substantially parallel to the first direction DR1. The first-first intermediate metal layer MMP1-1 may include a first-first side surface SS1-1 that forms a first-first angle AG1-1 with respect to the first-first upper surface US1-1. The first-first angle AG1-1 may be equal to or greater than about 45 degrees and equal to or smaller than about 80 degrees. For example, the first-first angle AG1-1 may be about 60 degrees. Each of the first-first lower metal layer LMP1-1 and the first-first upper metal layer HMP1-1 may include titanium (Ti). The first-first intermediate metal layer MMP1-1 may include aluminum (Al).

Each of a thickness d1 of the first-first lower metal layer LMP1-1 and a thickness d3 of the first-first upper metal layer HMP1-1 may be equal to or greater than about 10 nm and equal to or smaller than about 500 nm. The first-first intermediate metal layer MMP1-1 may have a thickness d2 equal to or greater than about 300 nm and equal to or smaller than about 2000 nm. For example, each of the thickness d1 of the first-first lower metal layer LMP1-1 and the thickness d3 of the first-first upper metal layer HMP1-1 may be about 100 nm, and the thickness d2 of the first-first intermediate metal layer MMP1-1 may be about 1000 nm.

The first-second metal pattern MP1-2 may be spaced apart from the first-first metal pattern MP1-1 in the first direction DR1. The first-second metal pattern MP1-2 may include a first-second lower metal layer LMP1-2 disposed on the first auxiliary insulating layer 40, a first-second intermediate metal layer MMP1-2 disposed on the first-second lower metal layer LMP1-2, and a first-second upper metal layer HMP1-2 disposed on the first-second intermediate metal layer MMP1-2.

The first-second lower metal layer LMP1-2 may be disposed (or directly disposed) on the first auxiliary insulating layer 40. The first-second lower metal layer LMP1-2 may include a first-second upper surface US1-2 substantially parallel to the first direction DR1. The first-second intermediate metal layer MMP1-2 may include a first-second side surface SS1-2 that forms a first-second angle AG1-2 with respect to the first-second upper surface US1-2. The first-second angle AG1-2 may be equal to or greater than about 45 degrees and equal to or smaller than about 80 degrees. For example, the first-second angle AG1-2 may be about 60 degrees. Each of the first-second lower metal layer LMP1-2 and the first-second upper metal layer HMP1-2 may include titanium (Ti). The first-second intermediate metal layer MMP1-2 may include aluminum (Al).

Each of a thickness d7 of the first-second lower metal layer LMP1-2 and a thickness d9 of the first-second upper metal layer HMP1-2 may be equal to or greater than about 10 nm and equal to or smaller than about 500 nm. The first-second intermediate metal layer MMP1-2 may have a thickness d8 equal to or greater than about 300 nm and equal to or smaller than about 2000 nm. For example, each of the thickness d7 of the first-second lower metal layer LMP1-2 and the thickness d9 of the first-second upper metal layer HMP1-2 may be about 100 nm, and the thickness d8 of the first-second intermediate metal layer MMP1-2 may be about 1000 nm.

The first lower metal layer LMP1 may include the first-first lower metal layer LMP1-1 and the first-second lower metal layer LMP1-2. The first intermediate metal layer MMP1 may include the first-first intermediate metal layer MMP1-1 and the first-second intermediate metal layer MMP1-2. The first upper metal layer HMP1 may include the first-first upper metal layer HMP1-1 and the first-second upper metal layer HMP1-2. The first upper surface US1 may include the first-first upper surface US1-1 and the first-second upper surface US1-2. The first side surface SS1 may include the first-first side surface SS1-1 and the first-second side surface SS1-2. The first angle AG1 may include the first-first angle AG1-1 and the first-second angle AG1-2.

The second metal pattern MP2 may be disposed on the first auxiliary insulating layer 40 and may be disposed in the opening OP. The second metal pattern MP2 may not be in contact with the cover layer CL. The second metal pattern MP2 may overlap the contact area CA in a plan view. The second metal pattern MP2 may transmit the second driving voltage ELVSS (refer to FIG. 4B) to the pixels PX. The second metal pattern MP2 may prevent the second driving voltage ELVSS (refer to FIG. 4B) applied to the second electrode CE of the light emitting element disposed at the center of the display device from decreasing. The second metal pattern MP2 may be spaced apart from the first metal pattern MP1 in a plan view. The second metal pattern MP2 may be disposed between the first-first metal pattern MP1-1 and the first-second metal pattern MP1-2 in the first direction DR1. For example, the first-first metal pattern MP1-1, the second metal pattern MP2, and the first-second metal pattern MP1-2 may be sequentially arranged in the first direction DR1. Each of a distance L1 between the first-first metal pattern MP1-1 and the second metal pattern MP2 in the first direction DR1 and a distance L2 between the second metal pattern MP2 and the first-second metal pattern MP1-2 in the first direction DR1 may be equal to or greater than about 0.5 micrometers (μm) and equal to or smaller than about 5 μm. For example, each of the distance L1 between the first-first metal pattern MP1-1 and the second metal pattern MP2 in the first direction DR1 and the distance L2 between the second metal pattern MP2 and the first-second metal pattern MP1-2 in the first direction DR1 may be about 2 μm.

The second metal pattern MP2 may include a metal material. For example, the second metal pattern MP2 may include at least one of aluminum (Al) or titanium (Ti). The second metal pattern MP2 may include a second lower metal layer LMP2, a second intermediate metal layer MMP2, and a second upper metal layer HMP2.

The second lower metal layer LMP2 may be disposed on the first auxiliary insulating layer 40. The second lower metal layer LMP2 may be disposed (or directly disposed) on the first auxiliary insulating layer 40. The second lower metal layer LMP2 may include a second upper surface US2 substantially parallel to the first direction DR1.

The second intermediate metal layer MMP2 may be disposed on the second lower metal layer LMP2. The second intermediate metal layer MMP2 may be spaced apart from the cover layer CL in the first direction DR1. The second intermediate metal layer MMP2 may include a second side surface SS2. The second side surface SS2 may include a second-first side surface SS2-1 that forms a second-first angle AG2-1 with respect to the second upper surface US2 and a second-second side surface SS2-2 that forms a second-second angle AG2-2 with respect to the second upper surface US2. Each of the second-first angle AG2-1 and the second-second angle AG2-2 may be equal to or greater than about 45 degrees and equal to or smaller than about 80 degrees. For example, each of the second-first angle AG2-1 and the second-second angle AG2-2 may be about 60 degrees.

The second upper metal layer HMP2 may be disposed on the second intermediate metal layer MMP2. The second upper metal layer HMP2 may include a second lower surface LS2. The second lower surface LS2 may include a second-first lower surface LS2-1 overlapping the second-first side surface SS2-1 in a plan view and a second-second lower surface LS2-2 overlapping the second-second side surface SS2-2 in a plan view. Each of the second-first lower surface LS2-1 and the second-second lower surface LS2-2 may be substantially parallel to the first direction DR1. Each of a width in the first direction DR1 of the second-first lower surface LS2-1 and a width in the first direction DR1 of the second-second lower surface LS2-2 may be equal to or greater than about 0.1 μm and equal to or smaller than about 1.5 μm. For example, each of the width in the first direction DR1 of the second-first lower surface LS2-1 and the width in the first direction DR1 of the second-second lower surface LS2-2 may be about 1 micrometer.

Each of the second lower metal layer LMP2 and the second upper metal layer HMP2 may include titanium (Ti). The second intermediate metal layer MMP2 may include aluminum (Al).

Each of a thickness d4 of the second lower metal layer LMP2 and a thickness d6 of the second upper metal layer HMP2 may be equal to or greater than about 10 nm and equal to or smaller than about 500 nm. The second intermediate metal layer MMP2 may have a thickness d5 equal to or greater than about 300 nm and equal to or smaller than about 2000 nm. For example, each of the thickness d4 of the second lower metal layer LMP2 and the thickness d6 of the second upper metal layer HMP2 may be about 100 nm, and the thickness d5 of the second intermediate metal layer MMP2 may be about 1000 nm.

The dummy pattern DMP may be disposed on the second metal pattern MP2. The dummy pattern DMP may be disposed (or directly disposed) on the second metal pattern MP2. The dummy pattern DMP may include a first dummy layer DMP1 disposed on the second upper metal layer HMP2, a second dummy layer DMP2 disposed on the first dummy layer DMP1, and a third dummy layer DMP3 disposed on the second dummy layer DMP2. The first dummy layer DMP1 may include the same material as that of the intermediate layer ML. The second dummy layer DMP2 may include the same material as that of the second electrode CE. The third dummy layer DMP3 may include the first material included in the cover layer CL. The dummy pattern DMP may not be in contact with the intermediate layer ML, the second electrode CE, and the cover layer CL. The dummy pattern DMP may further include a fourth dummy layer DMP4 disposed on the third dummy layer DMP3. The fourth dummy layer DMP4 may include the same material as that of the capping layer CPL. The fourth dummy layer DMP4 may not be in contact with the capping layer CPL.

The first structure CT1 may be electrically connected to the second electrode CE and may be in direct contact with each of the second intermediate metal layer MMP2 and the second upper metal layer HMP2. The first structure CT1 may be in direct contact with at least a portion of the second-first side surface SS2-1 and at least a portion of the second-first lower surface LS2-1. For example, the first structure CT1 may be in direct contact with a portion of the second-first side surface SS2-1 and an entire portion of the second-first lower surface LS2-1. The first structure CT1 may not overlap the cover layer CL in a plan view. A surface of the first structure CT1, which is in direct contact with the second intermediate metal layer MMP2, may be disposed adjacent to the second upper metal layer HMP2. A surface of the intermediate layer ML, which is in direct contact with the second intermediate metal layer MMP2, may be disposed adjacent to the second lower metal layer LMP2. The surface of the first structure CT1, which is in direct contact with the second intermediate metal layer MMP2, may not overlap the surface of the intermediate layer ML, which is in direct contact with the second intermediate metal layer MMP2, in the first direction DR1. The surface of the first structure CT1, which is in direct contact with the second intermediate metal layer MMP2, may correspond to a portion of the second-first side surface SS2-1 except the surface that is in direct contact with the intermediate layer ML.

According to a conventional display device, a voltage drop and a brightness reduction occur in an area far from a power supply voltage due to a resistance of electrodes. The second metal pattern MP2 included in the display device according to the disclosure may transmit the second driving voltage ELVSS (refer to FIG. 4B) to the pixels PX. The second metal pattern MP2 may prevent the second driving voltage ELVSS (refer to FIG. 4B) applied to the second electrode CE of the light emitting element disposed at the center of the display device from being reduced.

The first structure CT1 may include a second material. The first structure CT1 may include the same material as that of the second electrode CE. The second material may include at least one of indium tin oxide (ITO), indium zinc oxide (IZO), zinc oxide (ZnO), indium tin zinc oxide (ITZO), Ag, Mg, Cu, Al, Pt, Pd, Au, Ni, Nd, Ir, Cr, Li, Ca, LiF/Ca, LiF/Al, Mo, Ti, Yb, and Bi. For example, the second material may include titanium (Ti).

The surface energy of the first material included in the cover layer CL may be smaller than a surface energy of the second material included in the first structure CT1. The surface energy of the first material may be greater than about 0 mJ/m² and equal to or smaller than about 30 mJ/m². The surface energy of the second material may be equal to or greater than about 500 mJ/m² and equal to or smaller than about 1000 mJ/m². For example, the surface energy of the first material may be about 15 mJ/m², and the surface energy of the second material may be about 700 mJ/m².

The display element layer DP-OLED (refer to FIG. 6) may further include a second structure CT2 (or a second member CT2). The second structure CT2 may be spaced apart from the first structure CT1 in the first direction DR1. The second structure CT2 may be electrically connected to the second electrode CE and may be in direct contact with each of the second intermediate metal layer MMP2 and the second upper metal layer HMP2. The second structure CT2 may be in direct contact with at least a portion of the second-second side surface SS2-2 and at least a portion of the second-second lower surface LS2-2. For example, the second structure CT2 may be in direct contact with a portion of the second-second side surface SS2-2 and an entire portion of the second-second lower surface LS2-2. The second structure CT2 may not overlap the cover layer CL in a plan view. A surface of the second structure CT2, which is in direct contact with the second intermediate metal layer MMP2, may be disposed adjacent to the second upper metal layer HMP2. A surface of the intermediate layer ML, which is in direct contact with the second intermediate metal layer MMP2, may be disposed adjacent to the second lower metal layer LMP2. For example, a surface of the intermediate layer ML, which is in direct contact with the second-second side surface SS2-2, may be disposed adjacent to the second lower metal layer LMP2. A surface of the second structure CT2, which is in direct contact with the second-second side surface SS2-2, may not overlap the surface of the intermediate layer ML, which is in direct contact with the second-second side surface SS2-2, in the first direction DR1. The surface of the second structure CT2, which is in direct contact with the second-second side surface SS2-2, may correspond to a portion of the second-second side surface SS2-2 except the surface that is in direct contact with the intermediate layer ML.

In comparison with the case where the display device of the disclosure includes only the first structure CT1, in case that the display device of the disclosure includes both the first structure CT1 and the second structure CT2, the second metal pattern MP2 may transmit the second driving voltage ELVSS (refer to FIG. 4B) to the second electrode CE through the first structure CT1 and the second structure CT2. Accordingly, the resistance of electrode may be reduced, and thus, the voltage drop and the brightness reduction may be improved.

The second structure CT2 may include the second material. For example, the second material may include titanium (Ti). The surface energy of the first material included in the cover layer CL may be smaller than the surface energy of the second material included in the second structure CT2.

Hereinafter, a manufacturing method of the display device according to the disclosure will be described. Detailed descriptions on components described with reference to FIGS. 1 to 7 will be omitted.

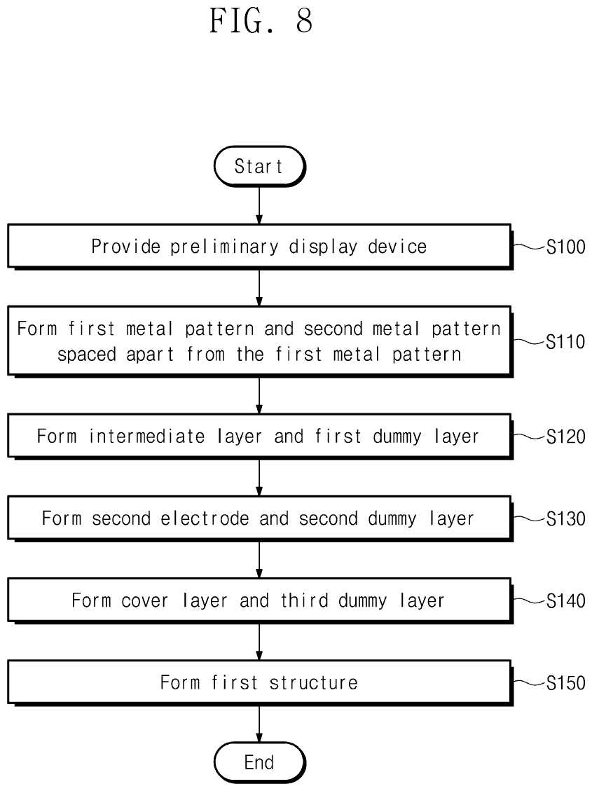

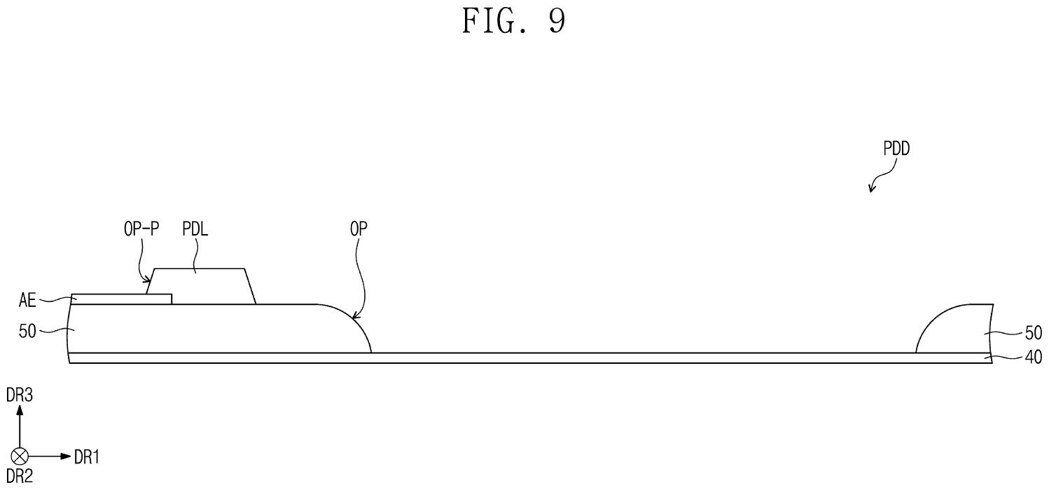

FIG. 8 is a schematic flowchart of the method of manufacturing the display device according to an embodiment of the disclosure. FIGS. 9 to 15 are schematic cross-sectional views illustrating the method of manufacturing the display device according to an embodiment of the disclosure.

Referring to FIG. 8, the manufacturing method of the display device may include providing a preliminary display device (S100), forming the first metal pattern and the second metal pattern spaced apart from the first metal pattern (S110), forming the intermediate layer and the first dummy layer (S120), forming the second electrode and the second dummy layer (S130), forming the cover layer and the third dummy layer (S140), and forming the first structure (S150).

Referring to FIG. 9, the preliminary display device PDD may include the first auxiliary insulating layer 40, the second auxiliary insulating layer 50 provided with the opening OP defined therethrough and disposed on the first auxiliary insulating layer 40, the pixel definition layer PDL disposed on the second auxiliary insulating layer 50 and provided with the pixel opening OP-P defined therethrough, and the first electrode AE of which at least a portion is disposed in the pixel opening OP-P.

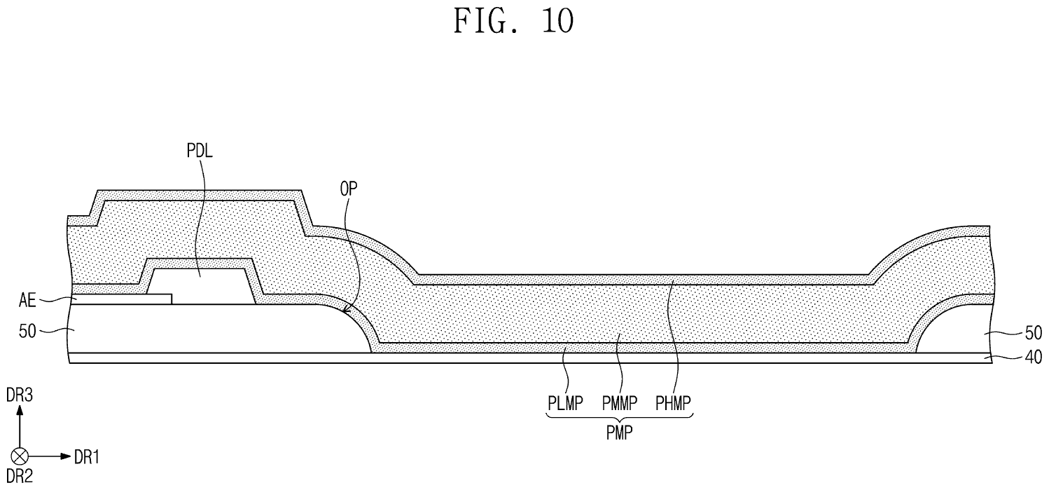

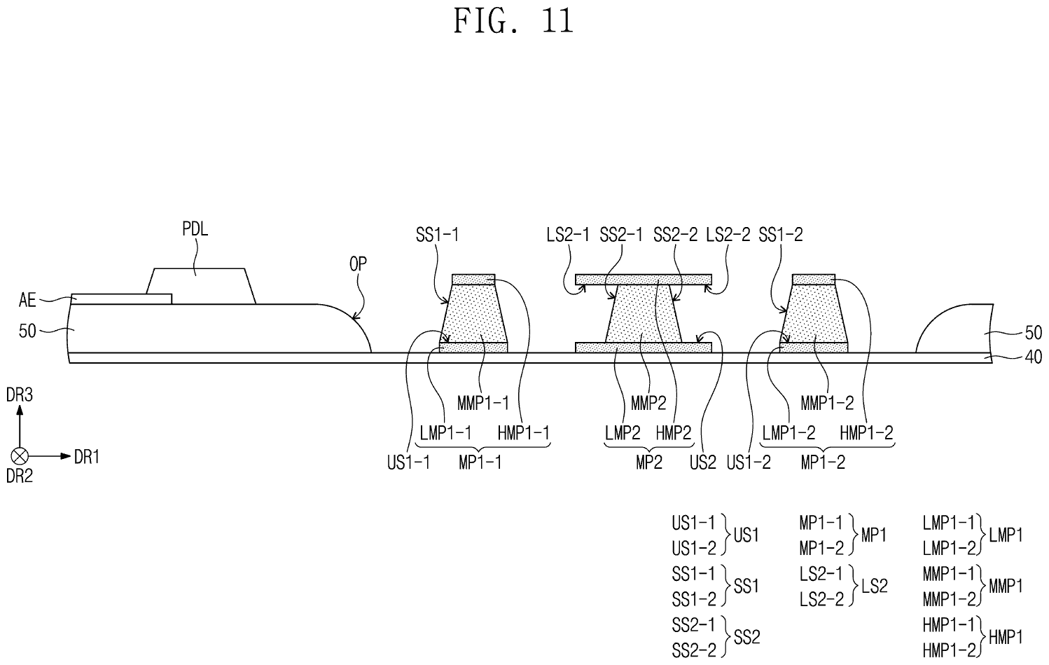

Referring to FIGS. 10 and 11, the forming of the first metal pattern MP1 and the second metal pattern MP2 spaced apart from the first metal pattern MP1 may include forming a preliminary metal pattern PMP and etching a portion of the preliminary metal pattern PMP. In the forming of the preliminary metal pattern PMP, the preliminary metal pattern PMP may include a preliminary lower metal layer PLMP disposed on the first electrode AE, the pixel definition layer PDL, the first auxiliary insulating layer 40, and the second auxiliary insulating layer 50, a preliminary intermediate metal layer PMMP disposed on the preliminary lower metal layer PLMP, and a preliminary upper metal layer PHMP disposed on the preliminary intermediate metal layer PMMP. Each of the preliminary lower metal layer PLMP and the preliminary upper metal layer PHMP may include titanium (Ti). The preliminary intermediate metal layer PMMP may include aluminum (Al). The portion of the preliminary metal pattern PMP may be etched by a dry etching process or a wet etching process. In case that the portion of the preliminary metal pattern PMP is etched, the first-first metal pattern MP1-1, the second metal pattern MP2, and the first-second metal pattern MP1-2 may be formed to be sequentially arranged in the first direction DR1. For example, portions of the preliminary metal pattern PMP, which are disposed on the first electrode AE, the pixel definition layer PDL, and the second auxiliary insulating layer 50, may be etched.

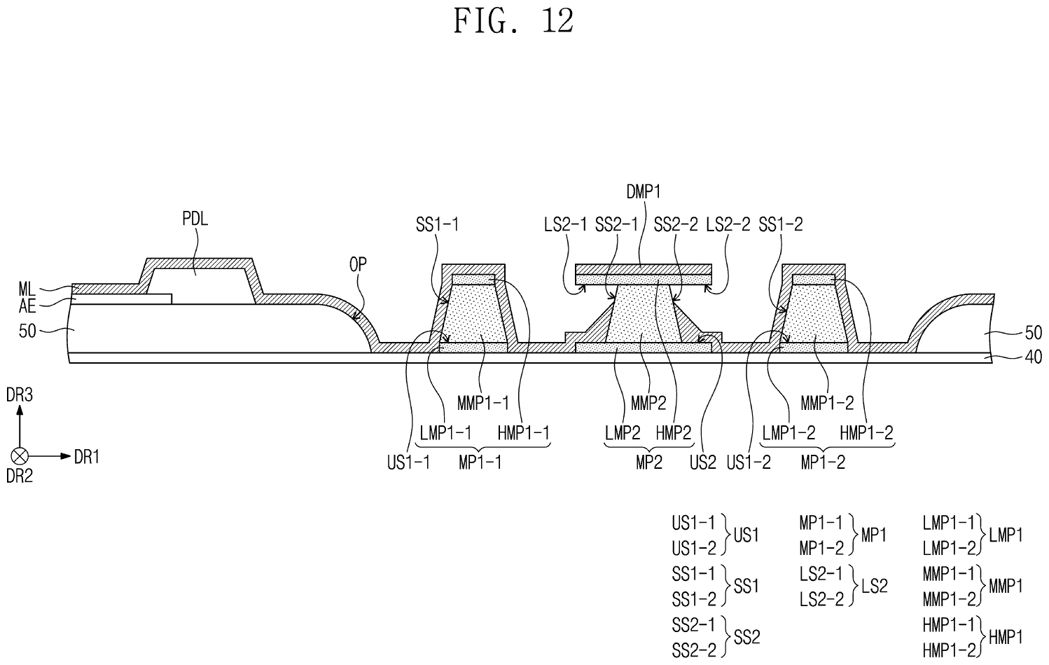

Referring to FIG. 12, in the forming of the intermediate layer ML and the first dummy layer DMP1, the intermediate layer ML may be formed to be in contact with a portion of the second-first side surface SS2-1 and a portion of the second-second side surface SS2-2. Each of the second-first side surface SS2-1 and the second-second side surface SS2-2 may include a portion that is not in contact with the intermediate layer ML.

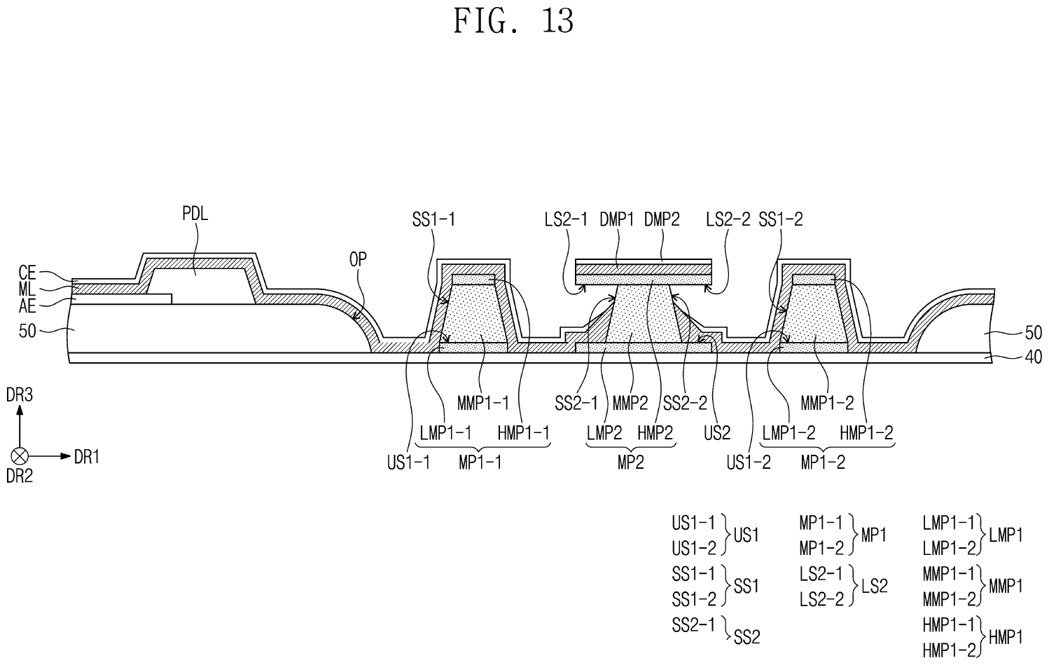

Referring to FIG. 13, the second electrode CE may be disposed on the intermediate layer ML in the forming of the second electrode CE and the second dummy layer DMP2. The second dummy layer DMP2 may be disposed on the first dummy layer DMP1. The second electrode CE and the second dummy layer DMP2 may be simultaneously formed. The second electrode CE may be formed by a physical vapor deposition (PVD) process. The second electrode CE may be formed through a thermal evaporation method. The second electrode CE may not be in direct contact with the second metal pattern MP2.

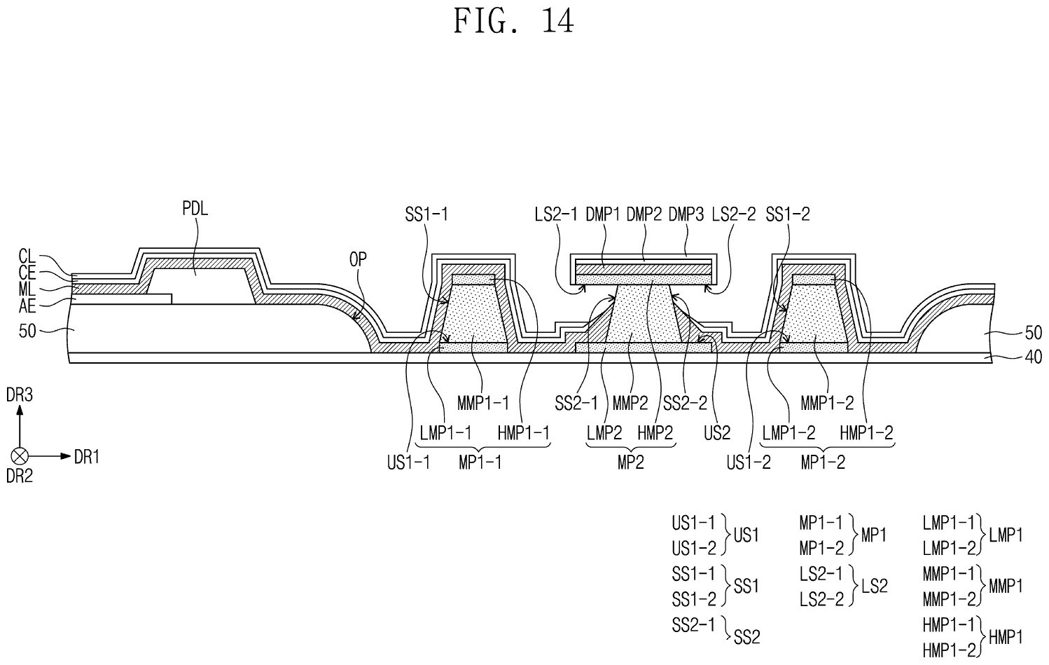

Referring to FIG. 14, the cover layer CL may include the first material in the forming of the cover layer CL and the third dummy layer DMP3. The cover layer CL may be disposed on the second electrode CE. The third dummy layer DMP3 may be disposed on the second dummy layer DMP2. The cover layer CL may not be disposed on the portion of the second electrode CE, which is disposed adjacent to the second metal pattern MP2. For example, at least a portion of the second electrode CE may not be covered by the cover layer CL.

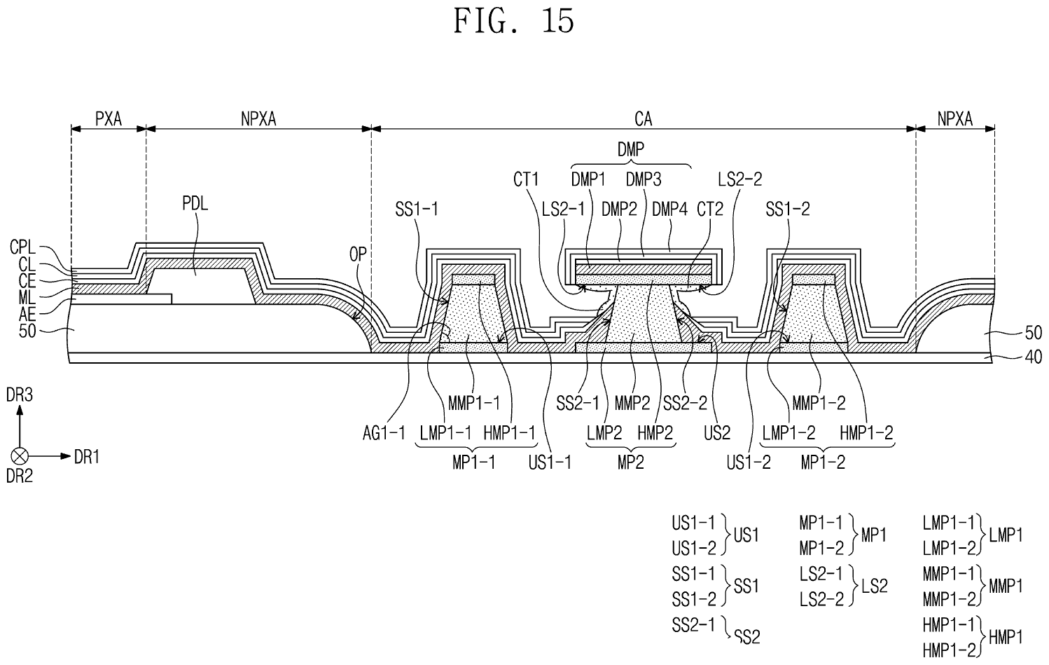

Referring to FIG. 15, the forming of the first structure CT1 may include depositing the second material on the cover layer CL through a thermal evaporation method. The surface energy of the second material provided on the cover layer CL may be greater than the surface energy of the first material included in the cover layer CL. Accordingly, the second material directly provided onto the cover layer CL may not be deposited due to the difference in surface energy between the first material and the second material and may be deposited on the portion where the cover layer CL is not disposed. The portion where the cover layer CL is not disposed may include a portion of the intermediate layer ML, a portion of the second-first side surface SS2-1, and at least a portion of the second-first lower surface LS2-1. The second material provided on the portion of the intermediate layer ML, the portion of the second-first side surface SS2-1, and at least the portion of the second-first lower surface LS2-1 may form the first structure CT1. The second material may be provided on the cover layer CL through a thermal evaporation process, and the thermal evaporation process has low process difficulty and high economic efficiency compared to a sputtering method.

In case that the second material is provided on the cover layer CL, the second material sprayed to the cover layer CL may collide with the first metal pattern MP1. A portion of the second material sprayed to the cover layer CL may move and may be provided on the second-first side surface SS2-1 after colliding with the cover layer CL deposited on the first-first side surface SS1-1 forming the first-first angle AG1-1 with the first-first upper surface US1-1. Another portion of the second material sprayed to the cover layer CL may move and may be provided on the second-first lower surface LS2-1 after colliding with the cover layer CL disposed between the first-first metal pattern and the second metal pattern. According to the display device manufactured by the manufacturing method of the display device according to the disclosure, the second metal pattern MP2 may transmit the second driving voltage ELVSS (refer to FIG. 4B) to the second electrode CE through the first structure CT1. Accordingly, the resistance of electrode may be reduced, and thus, the voltage drop and the brightness reduction may be improved.

The manufacturing method of the display device may further include forming the second structure CT2 after the forming of the first structure CT1. The forming of the second structure CT2 may include depositing the second material on the cover layer CL through a thermal evaporation method. The surface energy of the second material provided on the cover layer CL may be greater than the surface energy of the first material included in the cover layer CL. Accordingly, the second material directly provided on the cover layer CL may not be deposited due to the difference in surface energy between the first and second materials and may be deposited on the portion where the cover layer CL is not disposed. The portion where the cover layer CL is not disposed may include a portion of the intermediate layer ML, a portion of the second-second side surface SS2-2, and at least a portion of the second-second lower surface LS2-2. The second material provided on the portion of the intermediate layer ML, the portion of the second-second side surface SS2-2, and at least the portion of the second-second lower surface LS2-2 may form the second structure CT2. In case that the display device manufactured by the manufacturing method of the display device of the disclosure further includes the second structure CT2, the second metal pattern MP2 may transmit the second driving voltage ELVSS (refer to FIG. 4B) to the second electrode CE through the first structure CT1 and the second structure CT2 compared with the case where the display device includes only the first structure CT1. Accordingly, the resistance of electrode may be reduced, and thus, the voltage drop and the brightness reduction may be improved.

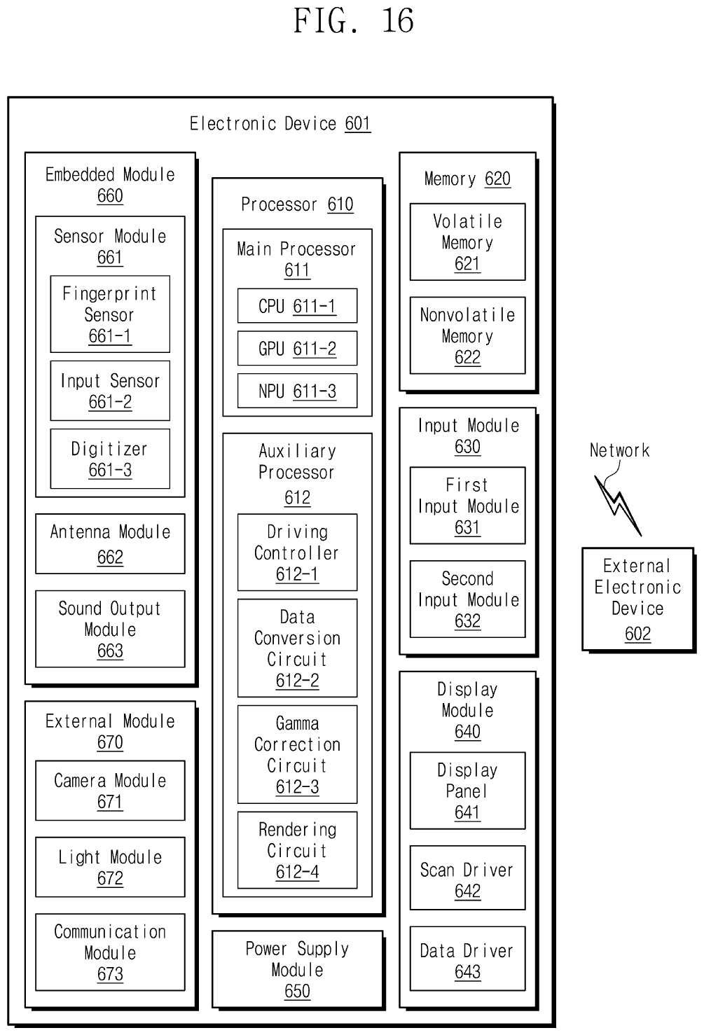

FIG. 16 is a schematic block diagram of an electronic device, according to an embodiment of the disclosure.

Referring to FIG. 16, an electronic device 601 outputs various pieces of information through a display module 640 within an operating system. In case that a processor 610 executes an application stored in a memory 620, a display module 640 provides application information to a user through a display panel 641.

The processor 610 obtains an external input through an input module 630 or a sensor module 661 and executes an application corresponding to the external input. For example, in case that the user selects a camera icon displayed on the display panel 641, the processor 610 obtains a user input through an input sensor 661-2 and activates a camera module 671. The processor 610 delivers image data corresponding to a captured image obtained through the camera module 671 to the display module 640. The display module 640 may display an image corresponding to the captured image through the display panel 641.

For another example, in case that personal information is authenticated on the display module 640, a fingerprint sensor 661-1 obtains entered fingerprint information as input data. The processor 610 compares input data obtained through the fingerprint sensor 661-1 with authentication data stored in the memory 620 and executes an application based on the comparison result. The display module 640 may display information, which is executed depending on the logic of the application, through the display panel 641.

For another example, in case that a music streaming icon displayed on the display module 640 is selected, the processor 610 may obtain a user input through the input sensor 661-2 and may activate the music streaming application stored in the memory 620. In case that a music play command is input by the music streaming application, the processor 610 may provide sound information corresponding to the music play command to the user by activating a sound output module 663.

The operation of the electronic device 601 has been briefly described above. Hereinafter, a configuration of the electronic device 601 will be described in detail. Some of components of the electronic device 601, which will be described below, may be integrated and provided as one configuration, or the one configuration may be provided to be separated into two or more configurations.

Referring to FIG. 16, the electronic device 601 may communicate with an external electronic device 602 through a network (e.g., a short-range wireless communication network or a long-range wireless communication network). The electronic device 601 may include the processor 610, the memory 620, the input module 630, the display module 640, a power supply module 650, an embedded module 660, and an external module 670. In the electronic device 601, at least one of the above-described components may be omitted, or one or more other components may be added. Some of the components (e.g., the sensor module 661, an antenna module 662, or the sound output module 663) described above may be integrated into another component (e.g., the display module 640).

The processor 610 may execute software to control at least another component (e.g., hardware or software component) of the electronic device 601 connected to the processor 610, and may process and calculate various types of data. As at least part of data processing or calculation, the processor 610 may store instructions or data received from other components (e.g., the input module 630, the sensor module 661 or a communication module 673) into a volatile memory 621, may process instructions or data stored in the volatile memory 621. The result data may be stored in a nonvolatile memory 622.

The processor 610 may include a main processor 611 and an auxiliary processor 612. The main processor 611 may include one or more of a central processing unit (CPU) 611-1 or an application processor (AP). The main processor 611 may further include one or more of a graphic processing unit (GPU) 611-2, a communication processor (CP), and an image signal processor (ISP). The main processor 611 may further include a neural processing unit (NPU) 611-3. The NPU 611-3 may be a processor that is specialized in processing an artificial intelligence model. The artificial intelligence model may be generated through machine learning. The artificial intelligence model may include multiple artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the networks, but may not be limited to the above-described example. In addition to a hardware structure, the artificial intelligence model may include a software structure. At least two of the processing units and the processors that are described above may be implemented as one integrated component (e.g., a single chip) or may be implemented as independent components (e.g., multiple chips).

The auxiliary processor 612 may include a driving controller 612-1. The driving controller 612-1 may include an interface converting circuit and a timing control circuit. The driving controller 612-1 may receive an image signal from the main processor 611, converts the data format of the image signal so as to be suitable for the interface specifications with the display module 640, and outputs image data. The driving controller 612-1 may output various control signals required to drive the display module 640.

The auxiliary processor 612 may further include a data converting circuit 612-2, a gamma correcting circuit 612-3, and a rendering circuit 612-4. The data converting circuit 612-2 may receive the image data from the driving controller 612-1 and may compensates for the image data such that an image is displayed at a desired luminance according to characteristics of the electronic device 601 or setting of the user or may convert the image data to reduce power consumption or compensate for afterimages. The gamma correcting circuit 612-3 may convert the image data, a gamma reference voltage, or the like such that the image displayed on the electronic device 601 has desired gamma characteristics. The rendering circuit 612-4 may receive the image data from the driving controller 612-1 and may render the image data in consideration of a pixel arrangement of the display panel 641 applied to the electronic device 601. At least one of the data converting circuit 612-2, the gamma correcting circuit 612-3, and the rendering circuit 612-4 may be integrated into another component (e.g., the main processor 611 or the driving controller 612-1). At least one of the data converting circuit 612-2, the gamma correcting circuit 612-3, and the rendering circuit 612-4 may be integrated into a data driver 643.

The memory 620 may store various pieces of data, which are used by at least one component (e.g., the processor 610 or the sensor module 661) of the electronic device 601 and input data or output data for commands related thereto. The memory 620 may include at least one or more of the volatile memory 621 and the nonvolatile memory 622.

The input module 630 may receive, from the outside (e.g., the user or an external electronic device 602) of the electronic device 601, commands or data to be used in a components (e.g., the processor 610, the sensor module 661, or the sound output module 663) of the electronic device 601.

The input module 630 may include a first input module 631, through which the commands or data are input from the user, and a second input module 632 through which the commands or data are input from the external electronic device 602. The first input module 631 may include a microphone, a mouse, a keyboard, a key (e.g., a button), or a pen (e.g., a passive pen or an active pen). The second input module 632 may support a designated protocol capable of being connected to the external electronic device 602 by wire or wirelessly. The second input module 632 may include a high definition multimedia interface (HDMI), a universal serial bus (USB) interface, a secure digital (SD) card interface, or an audio interface. The second input module 632 may include a connector that may be physically connected to the external electronic device 602, for example, an HDMI connector, a USB connector, an SD card connector, or an audio connector (e.g., a headphone connector).

The display module 640 may provide visual information to the user. The display module 640 may include the display panel 641, a scan driver 642, and the data driver 643. The display module 640 may further include a window, a chassis, a bracket, or the like for protecting the display panel 641. The display module 640 may further include a light emitting driver, a voltage generator, and the like. The voltage generator may output various voltages (e.g., the first and second driving voltages ELVDD and ELVSS (see FIG. 1)) required to drive the display panel 641.

The power supply module 650 may supply power to the components of the electronic device 601. The power supply module 650 may include a battery that charges a power voltage. The battery may include a non-rechargeable primary cell, a rechargeable secondary cell, a fuel cell, or the like. The power supply module 650 may include a power management integrated circuit (PMIC). The PMIC may supply optimized power to the above-described modules and modules which will be described below. The power supply module 650 may include a wireless power transmission/reception member electrically connected to the battery. The wireless power transmission/reception member may include multiple coil-shaped antenna radiators.

The electronic device 601 may further include the embedded module 660 and the external module 670. The embedded module 660 may include the sensor module 661, the antenna module 662, and the sound output module 663. The external module 670 may include the camera module 671, a light module 672, and the communication module 673.

The sensor module 661 may detect an input from the user's body or an input from a pen among the first input module 631, and may generate an electrical signal or data value corresponding to the input. The sensor module 661 may include at least one of the fingerprint sensor 661-1, the input sensor 661-2, and a digitizer 661-3.

The fingerprint sensor 661-1 may generate a data value corresponding to a fingerprint of the user. The fingerprint sensor 661-1 may include one of an optical-type fingerprint sensor, or a capacitance-type fingerprint sensor.

The input sensor 661-2 may generate a data value corresponding to coordinate information of an input by a body of the user or an input by a pen. The input sensor 661-2 generates the change in capacitance due to the input as the data value. The input sensor 661-2 may sense an input by a passive pen or may transmit or receive data to or from an active pen.

The input sensor 661-2 may also measure a biometric signal such as blood pressure, moisture, or body fat. For example, in case that the user touches a part of the body to a sensor layer or sensing panel and does not move during a specific period, the input sensor 661-2 may detect the biometric signal and may output information desired by the user to the display module 640 based on a changes in electric fields caused by the part of the body.

The digitizer 661-3 may generate the data value corresponding to coordinate information of an input by the pen. The digitizer 661-3 may generate an electromagnetic change amount due to the input as the data value. The digitizer 661-3 may sense input by the passive pen or transmit or receive data to or from the active pen.

At least one of the fingerprint sensor 661-1, the input sensor 661-2, and the digitizer 661-3 may be implemented as a sensor layer formed on the display panel 641 through a subsequent process. The fingerprint sensor 661-1, the input sensor 661-2, and the digitizer 661-3 may be placed on the upper side of the display panel 641, and one (e.g., the digitizer 661-3) of the fingerprint sensor 661-1, the input sensor 661-2, and the digitizer 661-3 may be placed on the lower side of the display panel 641.

At least two or more of the fingerprint sensor 661-1, the input sensor 661-2, and the digitizer 661-3 may be formed to be integrated into one sensing panel through the same process. In case that being integrated into one sensing panel, the sensing panel may be placed between the display panel 641 and a window placed on the upper side of the display panel 641. The sensing panel may be placed on a window, and the location of the sensing panel is not limited thereto.

At least one of the fingerprint sensor 661-1, the input sensor 661-2, and the digitizer 661-3 may be built into the display panel 641. For example, at least one of the fingerprint sensor 661-1, the input sensor 661-2, and the digitizer 661-3 may be simultaneously formed through a process of forming elements (e.g., a light emitting element, a transistor, or the like) included in the display panel 641.

Besides, the sensor module 661 may generate an electrical signal or a data value corresponding to the internal state or external state of the electronic device 601. For example, the sensor module 661 may further include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illumination sensor.

The antenna module 662 may include one or more antennas to transmit or receive the signal or power to or from an external source. The communication module 673 may transmit or receive the signal to or from the external electronic device through the antenna suitable for a communication method. An antenna pattern of the antenna module 662 may be integrated into the input sensor 661-2 or one component (e.g., the display panel 641) of the display module 640.

The sound output module 663 may be a device for outputting an audio signal to the outside of the electronic device 601 and, for example, may include a speaker used for general purposes, such as multimedia playback or recording playback, and a receiver used only for receiving a call. The receiver may be implemented separately from the speaker or may be integrated with the speaker. A sound output pattern of the sound output module 663 may be integrated into the display module 640.

The camera module 671 may shoot a still image or a video image. The camera module 671 may include one or more lenses, an image sensor, or an image signal processor. The camera module 671 may further include an infrared camera capable of measuring the presence or absence of the user, a position of the user, a gaze of the user, or the like. The light module 672 may provide light. The light module 672 may include a light emitting diode or a xenon lamp. The light module 672 may operate in conjunction with the camera module 671 or may operate independently from the camera module 1710.

The communication module 673 may support establishing a wired or wireless communication channel between the electronic device 601 and the external electronic device 602 and performing communication through the established communication channel. The communication module 673 may include one or all of wireless communication modules such as a cellular communication module, a short-range wireless communication module, or a global navigation satellite system (GNSS) communication module, or wired communication modules such as a local area network (LAN) communication module or a power line communication module. The communication module 673 may communicate with the external electronic device 602 through a short-range communication network such as Bluetooth, WiFi direct, or infrared data association (IrDA) or a long-range communication network such as a cellular network, Internet, or a computer network (e.g., the LAN or a wide area network (WAN)). The above-mentioned various communication modules 673 may be implemented into one chip or may be respectively implemented into separate chips.

The input module 630, the sensor module 661, the camera module 671, and the like may be utilized to control an operation of the display module 640 in conjunction with the processor 610.

The processor 610 outputs commands or data to the display module 640, the sound output module 663, the camera module 671, or the light module 672 based on input data received from the input module 630. For example, the processor 610 may generate image data in response to input data applied through a mouse, an active pen, or the like to output the generated image data to the display module 640 or may generate command data in response to the input data to output the generated command data to the camera module 671 or the light module 672. In case that no input data is received from the input module 630 during a specific period, the processor 610 may switch an operation mode of the electronic device 601 to a low-power mode or a sleep mode to reduce power consumed in the electronic device 601.

The processor 610 may output commands or data to the display module 640, the sound output module 663, the camera module 671, or the light module 672 based on sensing data received from the sensor module 661. For example, the processor 610 may compare authentication data authorized by the fingerprint sensor 661-1 with the authentication data stored in the memory 620, and then may execute an application depending on the comparison result. The processor 610 may execute commands or may output corresponding image data to the display module 640 based on sensing data sensed by the input sensor 661-2 or the digitizer 661-3. In case that the sensor module 661 includes a temperature sensor, the processor 610 receives temperature data regarding the measured temperature from the sensor module 661 and may further perform luminance correction on image data based on the temperature data.

The processor 610 may receive measurement data regarding the presence or absence of the user, the user's location, and the user's gaze from the camera module 671. The processor 610 may further perform luminance correction on the image data based on the measurement data. For example, the processor 610 that determines the presence or absence of the user through an input from the camera module 671 may output image data, of which the luminance is corrected, to the display module 640 through the data converting circuit 612-2 or the gamma correcting circuit 612-3.

Some of the components may be electrically connected to each other through communication methods between peripheral devices, for example, a bus, a general purpose input/output (GPIO), a serial peripheral interface (SPI), a mobile industry processor interface (MIPI), or an ultra-path interconnect (UPI) link and may exchange a signal (e.g., commands or data) between each other. The processor 610 may communicate with the display module 640 through a mutually promised interface, and for example, may use any one of the above-described communication methods, and the disclosure is not limited to the above-described communication methods.

The electronic device 601 according to various embodiments disclosed in the disclosure may be implemented with various types of devices. The electronic device 601 may include, for example, at least one of a portable communication device (e.g., a smart phone), a computer device, a portable multimedia device, a portable medical device, a camera, a wearable device, or a home appliance. The electronic device 601 according to an embodiment of this disclosure may not be limited to the above-described devices.

Although the embodiments of the disclosure have been described, it is understood that the disclosure should not be limited to these embodiments but various changes and modifications can be made by one ordinary skilled in the art within the spirit and scope of the disclosure as hereinafter claimed. Therefore, the disclosed subject matter should not be limited to any single embodiment described herein, and the scope of the disclosure shall be determined according to the attached claims.

What is claimed is:

1. A display device comprising:
a base layer;
a circuit element layer disposed on the base layer; and
a display element layer disposed on the circuit element layer and including a pixel definition layer, a light emitting element, a first structure, and a cover layer disposed on the light emitting element, the circuit element layer including:
a first auxiliary insulating layer;
a second auxiliary insulating layer including an opening and disposed on the first auxiliary insulating layer;
a first metal pattern disposed on the first auxiliary insulating layer and disposed in the opening;
a second metal pattern spaced apart from the first metal pattern and including a second lower metal layer disposed on the first auxiliary insulating layer and disposed in the opening, a second intermediate metal layer disposed on the second lower metal layer, and a second upper metal layer disposed on the second intermediate metal layer; and
a dummy pattern disposed on the second metal pattern, wherein
the pixel definition layer is disposed on the second auxiliary insulating layer and includes a pixel opening,
the light emitting element includes:
a first electrode of which at least a portion is disposed in the pixel opening,
an intermediate layer disposed on the first electrode, the pixel definition layer, the first auxiliary insulating layer, the second auxiliary insulating layer, the first metal pattern, and the second metal pattern, and
a second electrode disposed on the intermediate layer,
the first structure is electrically connected to the second electrode and in direct contact with the second intermediate metal layer and the second upper metal layer,
the cover layer includes a first material,
the first structure includes a second material, and
the first material has a surface energy smaller than a surface energy of the second material.

2. The display device of claim 1, wherein
the second lower metal layer includes a second upper surface substantially parallel to a first direction,
the second intermediate metal layer includes a second-first side surface forming a second-first angle with respect to the second upper surface and a second-second side surface forming a second-second angle with respect to the second upper surface,
the second upper metal layer includes a second-first lower surface overlapping the second-first side surface in a plan view and a second-second lower surface overlapping the second-second side surface in a plan view, and
the first structure is in direct contact with at least a portion of the second-first side surface and at least a portion of the second-first lower surface.

3. The display device of claim 2, wherein each of a width of the second-first lower surface in the first direction and a width of the second-second lower surface in the first direction is equal to or greater than about 0.1 μm and equal to or smaller than about 1.5 μm.

4. The display device of claim 2, wherein each of the second-first angle and the second-second angle is equal to or greater than about 45 degrees and equal to or smaller than about 80 degrees.

5. The display device of claim 1, wherein the first structure does not overlap the cover layer in a plan view.

6. The display device of claim 1, wherein the cover layer is directly disposed on the second electrode and is not in contact with the second metal pattern.

7. The display device of claim 1, wherein
the intermediate layer is in direct contact with the second intermediate metal layer,
a surface at which the intermediate layer is in contact with the second intermediate metal layer is disposed adjacent to the second lower metal layer, and
a surface at which the first structure is in contact with the second intermediate metal layer is disposed adjacent to the second upper metal layer.

8. The display device of claim 1, wherein the first metal pattern includes:
a first lower metal layer disposed on the first auxiliary insulating layer;
a first intermediate metal layer disposed on the first lower metal layer; and
a first upper metal layer disposed on the first intermediate metal layer.

9. The display device of claim 8, wherein
the first lower metal layer includes a first upper surface substantially parallel to a first direction,
the first intermediate metal layer includes a first side surface forming a first angle with respect to the first upper surface, and
the first angle is equal to or greater than about 45 degrees and equal to or smaller than about 80 degrees.

10. The display device of claim 1, wherein
the dummy pattern includes:
a first dummy layer;
a second dummy layer disposed on the first dummy layer; and
a third dummy layer disposed on the second dummy layer and including the first material,
the first dummy layer and the intermediate layer include a same material, and
the second dummy layer and the second electrode include a same material.

11. The display device of claim 1, wherein
each of the second lower metal layer and the second upper metal layer has a thickness equal to or greater than about 10 nm and equal to or smaller than about 500 nm, and
the second intermediate metal layer has a thickness equal to or greater than about 300 nm and equal to or smaller than about 2000 nm.

12. The display device of claim 1, further comprising:
a second structure that is in direct contact with the second intermediate metal layer and the second upper metal layer and electrically connected to the second electrode, wherein
the first metal pattern includes a first-first metal pattern and a first-second metal pattern spaced apart from the first-first metal pattern in a first direction,
the second metal pattern is disposed between the first-first metal pattern and the first-second metal pattern, and
the second structure is spaced apart from the first structure in the first direction.

13. The display device of claim 12, wherein each of a distance in the first direction between the first-first metal pattern and the second metal pattern and a distance in the first direction between the first-second metal pattern and the second metal pattern is equal to or greater than about 0.5 μm and equal to or smaller than about 5 μm.

14. The display device of claim 1, wherein the display element layer further includes a capping layer disposed on the cover layer.

15. The display device of claim 1, wherein the cover layer has a thickness equal to or greater than about 5 nm and equal to or smaller than about 50 nm.

16. The display device of claim 1, wherein the first material includes a fluorine compound.

17. The display device of claim 1, wherein the second material includes at least one of indium tin oxide (ITO), indium zinc oxide (IZO), zinc oxide (ZnO), indium tin zinc oxide (ITZO), Ag, Mg, Cu, Al, Pt, Pd, Au, Ni, Nd, Ir, Cr, Li, Ca, LiF/Ca, LiF/Al, Mo, Ti, Y b, and Bi.

18. The display device of claim 1, wherein
the first material has a surface energy greater than about 0 mJ/m² and equal to or smaller than about 30 mJ/m², and
the second material has a surface energy equal to or greater than about 500 mJ/m² and equal to or smaller than about 1000 mJ/m²

19. A method of manufacturing a display device, the method comprising:
providing a preliminary display device including a first auxiliary insulating layer, a second auxiliary insulating layer including an opening and disposed on the first auxiliary insulating layer, a pixel definition layer disposed on the second auxiliary insulating layer and including a pixel opening, and a first electrode of which at least a portion is disposed in the pixel opening;
forming a first metal pattern and a second metal pattern spaced apart from the first metal pattern in the opening;
forming an intermediate layer disposed on the first electrode, the pixel definition layer, the first auxiliary insulating layer, the second auxiliary insulating layer, and the first metal pattern and a first dummy layer disposed on the second metal pattern;
forming a second electrode disposed on the intermediate layer and a second dummy layer disposed on the first dummy layer;
forming a cover layer including a first material disposed on the second electrode and a third dummy layer disposed on the second dummy layer; and
providing a second material on the cover layer to form a first structure, wherein
the second metal pattern includes a second lower metal layer disposed in the opening and disposed on the first auxiliary insulating layer, a second intermediate metal layer disposed on the second lower metal layer, and a second upper metal layer disposed on the second intermediate metal layer,
the first structure is in direct contact with the second intermediate metal layer and the second upper metal layer, and
the first material of the cover layer has a surface energy smaller than a surface energy of the second material of the first structure.

20. An electronic device comprising:
a display device that provides an image, the display device including:
a base layer;
a circuit element layer disposed on the base layer; and
a display element layer disposed on the circuit element layer and including a pixel definition layer, a light emitting element, a first structure, and a cover layer disposed on the light emitting element, the circuit element layer including:
a first auxiliary insulating layer;
a second auxiliary insulating layer including an opening and disposed on the first auxiliary insulating layer;
a first metal pattern disposed on the first auxiliary insulating layer and disposed in the opening;
a second metal pattern spaced apart from the first metal pattern and including a second lower metal layer disposed on the first auxiliary insulating layer and disposed in the opening, a second intermediate metal layer disposed on the second lower metal layer, and a second upper metal layer disposed on the second intermediate metal layer; and
a dummy pattern disposed on the second metal pattern, wherein
the pixel definition layer is disposed on the second auxiliary insulating layer and includes a pixel opening,
the light emitting element includes:
a first electrode of which at least a portion is disposed in the pixel opening,
an intermediate layer disposed on the first electrode, the pixel definition layer, the first auxiliary insulating layer, the second auxiliary insulating layer, the first metal pattern, and the second metal pattern, and
a second electrode disposed on the intermediate layer,
the first structure is electrically connected to the second electrode and in direct contact with the second intermediate metal layer and the second upper metal layer,
the cover layer includes a first material,
the first structure includes a second material, and
the first material has a surface energy smaller than a surface energy of the second material.
